(19) United States
(12) Patent Application Publication
(10) Pub. No.: US 2017/0185478 A1
(43) Pub. Date: Jun. 29, 2017

(54) MEMORY CONTROLLER, STORAGE APPARATUS, INFORMATION PROCESSING SYSTEM, AND MEMORY CONTROLLER CONTROL METHOD

(71) Applicant: SONY CORPORATION, TOKYO (JP)

(72) Inventors: LUI SAKAI, KANAGAWA (JP); KEIICHI TSUTSUI, KANAGAWA (JP); YASUSHI FUJINAMI, TOKYO (JP); HIROYUKI IWAKI, KANAGAWA (JP); KEN ISHII, TOKYO (JP); NAOHIRO ADACHI, TOKYO (JP); RYOJI IKEGAYA, KANAGAWA (JP); KENICHI NAKANISHI, TOKYO (JP)

(73) Assignee: SONY CORPORATION, TOKYO (JP)

(21) Appl. No.: 15/325,191

(22) PCT Filed: Jun. 23, 2015
(86) PCT No.: PCT/JP2015/067958

§ 371 Date: Jan. 10, 2017

(30) Foreign Application Priority Data
Jul. 29, 2014 (JP) 2014-153447

(51) Int. Cl. G06F 11/10; G06F 3/06; G11C 29/52

(52) U.S. Cl. CPC G06F 11/1068; G11C 29/52; G06F 3/0619; G06F 3/064; G06F 3/0679

(57) ABSTRACT

The convenience of an information processing system is improved. In a memory controller of the information processing system, a request generation unit generates, with respect to a nonvolatile memory including a data area in which data is stored and a redundancy area in which a redundancy for performing error detection and error correction of the data is stored, a request of requesting writing or reading for any one of the data, and the redundancy, a code word constituted of the data and the redundancy. A control unit issues the generated request and controls writing and reading with respect to the nonvolatile memory.

### CROSS REFERENCE TO RELATED APPLICATIONS

This application is a U.S. National Phase of International Patent Application No. PCT/JP2015/067958 filed on Jun. 23, 2015, which claims priority benefit of Japanese Patent Application No. JP 2014-153447 filed in the Japan Patent Office on Jul. 29, 2014. Each of the above-referenced applications is hereby incorporated herein by reference in its entirety.

### TECHNICAL FIELD

The present technology relates to a memory controller, a storage apparatus, an information processing system, and a memory controller control method. Specifically, the present technology relates to a memory controller, a storage apparatus, an information processing system, and a memory controller control method for performing error detection and error correction of data.

### BACKGROUND ART

In related art, to improve reliability of data storage, used is an information processing system that uses an Error detection and Correction Code (ECC) for performing error detection and error correction of data. The information processing system generates an ECC and stores the ECC in a nonvolatile memory with data. At a time when the data is reproduced, on the basis of the ECC, error detection and error correction of the data is performed. The attempt is being made that the ECC is devised to improve long storage stability of data and improve reliability of the storage. For example, there has been proposed an information processing system that generates a standard ECC for performing error detection and error correction of data and generates an expansion ECC for performing the error detection and error correction with a plurality of pieces of data as a unit (see, for example, Patent Literature 1).

### CITATION LIST

### Patent Literature

Patent Literature 1: 2011-081776

### DISCLOSURE OF INVENTION

### Technical Problem

In the related-art technology mentioned above, the data and ECC are stored in a data area and an ECC area of the nonvolatile memory, respectively. However, it is impossible to individually access these areas from a host system, which raises a problem of inconvenience. For example, in the case where an ECC and management information relating to data are stored in an ECC area at the same time, only the management information may be a target to be accessed in some cases. The relate-art technology mentioned above cannot cope with this case.

The present technology has been made in view of the circumstances as described above, and has an object to enable individual writing and reading for a data area and an ECC area, to improve convenience of an information system.

It should be noted that, in the description below, the following terms are used. A bit system of an error correction code is referred to as parity. A bit system in which management information and a parity are combined is referred to as redundancy. Note that only a parity not including management information is also referred to as redundancy. A bit system in which data and redundancy are combined is referred to as code word. Generating a code word by adding, to data, redundancy of the data is referred to as coding. Reproducing original data from a code word is referred to as decoding.

### Solution to Problem

The present technology has been made to solve the problem described above. According to a first embodiment of the present technology, there is provided a memory controller including: a request generation unit that generates, with respect to a nonvolatile memory including a data area in which data is stored and a redundancy area in which a redundancy for performing error detection and error correction of the data is stored, a request of requesting writing or reading for any one of the data, the redundancy, and a code word constituted of the data and the redundancy; and a control unit that issues the generated request and controls writing and reading with respect to the nonvolatile memory. As a result, an operation of performing writing or reading for any one of the data, the redundancy, or the code word is provided.

Further, in the first embodiment, the data may be the page data in unit of page, the redundancy may be the page redundancy for performing error detection and error correction of the page data, the code word may be the page code word constituted of the page data and the page redundancy, and the request may be a request of requesting writing or reading for any one of the page data, the page redundancy, and the page code word. As a result, an operation of performing writing or reading for any one of the page data, the page redundancy, and the page code word is provided.

Further, in the first embodiment, the data may be the expansion data including the plurality of pages and the page data, the redundancy may be expansion redundancy for performing error detection and error correction of the expansion data and the page redundancy, the code word may be an expansion code word constituted of the expansion data and the expansion redundancy and the page code word, and the request may be a request of requesting writing or reading for any one of the page data, the page redundancy, the page code word, the expansion data, the expansion redundancy, and the expansion code word. As a result, an operation of performing writing or reading for any one of the page data, the page redundancy, the page code word, the expansion data, the expansion redundancy, and the expansion code word is provided.

Further, in the first embodiment, the data may be a code word block including a plurality of page code words, the expansion data, and the page data, the redundancy may be a composite redundancy for performing error detection and error correction of the code word block, the expansion redundancy, and the page redundancy, the code word may be a composite code word constituted of the code word block and the composite redundancy, the expansion code word, and the page code word, and the request may be a request of requesting writing or reading for any one of the page data, the page redundancy, the page code word, the expansion data, the expansion redundancy, the expansion code word, the code word block, the composite redundancy, and the composite code word. As a result, an operation of performing writing or reading for any one of the page data, the page redundancy, the page code word, the expansion data, the expansion redundancy, the expansion code word, the code word block, the composite redundancy, and the composite code word is provided.

Further, in the first embodiment, the data may be a data block constituted of a plurality of pieces of page data included in the code word block, the code word block, the expansion data, and the page data, the redundancy may be a redundancy block constituted of a plurality of page redundancies included in the code word block and the composite redundancy, the composite redundancy, the expansion redundancy, and the page redundancy, and the request may be a request of requesting writing or reading for any one of the page data, the page redundancy, the page code word, the expansion data, the expansion redundancy, the expansion code word, the code word block, the composite redundancy, the composite code word, the data block, and the redundancy block. As a result, an operation of performing writing for any one of the page data, the page redundancy, the page code word, the expansion data, the expansion redundancy, the expansion code word, the code word block, the composite redundancy, the composite code word, the data block, the redundancy block is provided.

Further, in the first embodiment, the page redundancy may be constituted of management information related to the page data and a parity for performing error detection and error correction of the page data and the management information, and the expansion redundancy may be constituted of expansion management information related to the expansion data and an expansion parity for performing error detection and error correction of the expansion data and the expansion management information. As a result, an operation is provided that the page redundancy is constituted of the management information and the parity for performing error detection and error correction of the page data and the management information, and the expansion redundancy is constituted of the expansion management information and the expansion parity for performing error detection and error correction of the expansion data and the expansion management information.

Further, in the first embodiment, the composite redundancy may be constituted of a management information block parity for performing error detection and error correction of a management information block including a plurality of pieces of management information included in the code word block and a code word block parity for performing error detection and error correction of the code word block. As a result, an operation is provided that the composite redundancy is constituted of the management information block parity for performing error detection and error correction of the management information block and the code word block parity.

Further, in the first embodiment, the page redundancy may be constituted of a management information parity for performing error detection and error correction of the management information, the management information, and a double parity for performing error detection and error correction of the page data, the management information, and the management information parity, and the expansion redundancy may be constituted of an expansion management information parity for performing error detection and error correction of the expansion management information, the expansion management information, and an expansion double parity for performing error detection and error correction of the expansion data, the expansion management information, and the expansion management information parity. As a result, an operation is provided that the page redundancy is constituted of the management information parity, the management information, and the double parity, and the expansion redundancy is constituted of the expansion management information parity and the expansion double parity.

Further, in the first embodiment, the memory controller may further include: a first coding unit that generates the page redundancy; a first decoding unit that performs error detection and error correction of the page data included in the page code word by the page redundancy included in the page code word; a second coding unit that generates the expansion redundancy; a second decoding unit that performs error detection and error correction of the expansion data included in the expansion code word by the expansion redundancy included in the expansion code word; a third coding unit that generates the composite redundancy; and a third decoding unit that performs error detection and error correction of the code word block included in the composite code word by the composite redundancy included in the composite code word. The control unit may further control a transfer of the page code word to the first decoding unit which is input from the nonvolatile memory in response to an output of the request of requesting the reading, a transfer of the expansion code word to the second decoding unit which is input from the nonvolatile memory in response to the output of the request of requesting reading, and a transfer of the composite code word to the third decoding unit which is input from the nonvolatile memory in response to the output of the request of requesting reading. As a result, an operation is provided that the redundancy is generated by the first coding unit, the second coding unit, and the third coding unit, and the decoding is performed by the first decoding unit, the second decoding unit, and the third decoding unit.

Further, according to a second embodiment of the present technology, there is provided a storage apparatus including: a nonvolatile memory including a data area in which data is stored and a redundancy area in which a redundancy for performing error detection and error correction of the data is stored; and a memory controller that controls the nonvolatile memory. The memory controller includes a request generation unit that generates, with respect to the nonvolatile memory, a request of requesting writing or reading for any one of the data, the redundancy, and a code word constituted of the data and the redundancy, and a control unit that issues the generated request and controls writing and reading with respect to the nonvolatile memory. As a result, an operation of performing writing for any one of the data, the redundancy, the code word is provided.

Further, in the second embodiment, the nonvolatile memory may be constituted of banks that store pages to which addresses are given with page addresses, the data area and the redundancy area are assigned to different banks, and the data and the redundancy that belong to the same code word are stored in the bank with the same page address. As a result, an operation is provided that the data and the redundancy that belong to the same code word are stored in the banks with the same page address.

Further, according to a third embodiment of the present technology, there is provided an information processing system including: a host computer that outputs a command of requesting writing or reading to a memory controller; a nonvolatile memory including a data area in which data is stored and a redundancy area in which a redundancy for performing error detection and error correction of the data is stored; and a memory controller that controls the nonvolatile memory on the basis of the command. The memory controller includes a request generation unit that generates, with respect to the nonvolatile memory, a request of requesting writing or reading for any one of the data, the redundancy, and a code word constituted of the data and the redundancy on the basis of the command, and a control unit that issues the generated request and controls writing and reading with respect to the nonvolatile memory. As a result, an operation of performing writing for any one of the data, the redundancy, and the code word is provided.

Further, according to a fourth embodiment of the present technology, there is provided a memory controller control method including: a request generation step of generating, with respect to a nonvolatile memory including a data area in which data is stored and a redundancy area in which a redundancy for performing error detection and error correction of the data is stored, a request of requesting writing or reading for any one of the data, the redundancy, and a code word constituted of the data and the redundancy; and a control step of issuing the generated request and controlling writing and reading with respect to the nonvolatile memory. As a result, an operation of performing writing for any one of the data, the redundancy, and the code word is provided.

### Advantageous Effects of Invention

According to the present technology, the data and the redundancy in unit of page are stored in the different areas in the memory, and the data, the redundancy, or the code word can be accessed with the same page address, with the result that an advantageous effect of improving the convenience of the information system can be exerted. It should be noted that, the effects described herein are not limited, and any effect described in this disclosure may be obtained.

### BRIEF DESCRIPTION OF DRAWINGS

FIG. 1 A diagram showing a configuration example of an information processing system according to a first embodiment of the present technology.

FIG. 2 A diagram showing a configuration example of a memory controller according to the first embodiment of the present technology.

FIG. 3 A diagram showing a configuration example of a memory according to the first embodiment of the present technology.

FIG. 4 A diagram showing a configuration example of a memory cell array according to the first embodiment of the present technology.

FIG. 5a, 5b and 5c Diagrams showing a configuration example of code words according to the first embodiment of the present technology.

FIG. 6 A diagram showing a configuration example of a redundancy according to the first embodiment of the present technology.

FIG. 7 A diagram showing a configuration example of a request according to the first embodiment of the present technology.

FIG. 8 A flowchart showing an example of a procedure of attributes of requests according to the first embodiment of the present technology.

FIG. 9 A diagram for explaining processing of a request (write of composite code word) according to the first embodiment of the present technology.

FIG. 10 A diagram for explaining processing of a request (write of code word block) according to the first embodiment of the present technology.

FIG. 11 A diagram for explaining processing of a request (write of data block) according to the first embodiment of the present technology.

FIG. 12 A diagram for explaining processing of a request (write of redundancy block) according to the first embodiment of the present technology.

FIG. 13 A diagram for explaining processing of a request (write of composite redundancy) according to the first embodiment of the present technology.

FIG. 14 A diagram for explaining processing of a request (read of composite code word) according to the first embodiment of the present technology.

FIG. 15 A diagram for explaining processing of a request (read of code word block) according to the first embodiment of the present technology.

FIG. 16 A diagram for explaining processing of a request (read of data block) according to the first embodiment of the present technology.

FIG. 17 A diagram for explaining processing of a request (read of redundancy block) according to the first embodiment of the present technology.

FIG. 18 A diagram for explaining processing of a request (read of composite redundancy) according to the first embodiment of the present technology.

FIG. 19 A flowchart showing an example of a procedure of a write process (memory controller) according to the first embodiment of the present technology.

FIG. 20 A flowchart showing an example of a procedure of a redundancy generation process (memory controller) according to the first embodiment of the present technology.

FIG. 21 A flowchart showing an example of a procedure of a data and redundancy output process (memory controller) according to the first embodiment of the present technology.

FIG. 22 A flowchart showing an example of a procedure of a write process (memory) according to the first embodiment of the present technology.

FIG. 23 A flowchart showing an example of a procedure of data and redundancy transfer process (memory) according to the first embodiment of the present technology.

FIG. 24 A flowchart showing an example of a procedure of a read process (memory controller) according to the first embodiment of the present technology.

FIG. 25 A flowchart showing an example of a procedure of a data and redundancy reception process (memory controller) according to the first embodiment of the present technology.

FIG. 26 A flowchart showing an example of a procedure of a decoding process (memory controller) according to the first embodiment of the present technology.

FIG. 27 A flowchart showing an example of a procedure of a read process (memory) according to the first embodiment of the present technology.

FIG. 28 A flowchart showing an example of a procedure of data and redundancy transfer process (memory) according to the first embodiment of the present technology.

FIG. 29 A diagram showing a configuration example of redundancy according to a second embodiment of the present technology.

FIG. 30 A diagram showing a configuration example of a memory controller according to the second embodiment of the present technology.

FIG. 31 A diagram showing a configuration example of redundancy according to a modified example of the second embodiment of the present technology.

FIG. 32 A diagram showing a configuration example of a memory controller according to a third embodiment of the present technology.

FIG. 33a and 33b Diagrams showing transfer procedures of data and redundancy according to the third embodiment of the present technology.

FIG. 34 A diagram showing a configuration example of redundancy according to a modified example of the present technology.

### MODE(S) FOR CARRYING OUT THE INVENTION

Hereinafter, embodiments for carrying out the present technology (referred to as embodiments hereinafter) will be described. The description will be given in the following order.

1. First embodiment (Example in which redundancy includes parity and management information)

2. Second embodiment (Example in which redundancy includes parity, parity of management information, and management information)

3. Third embodiment (Example in which data buffer is omitted)

4. Modified example

### 1. First Embodiment

[Configuration Example of Information Processing System]

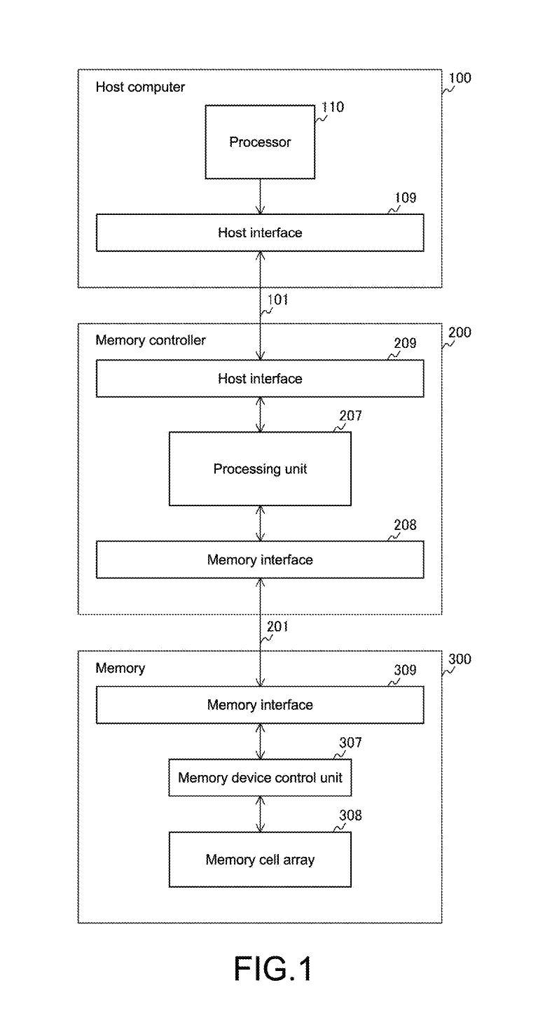

FIG. 1 is a diagram showing a configuration example of an information processing system according to a first embodiment of the present technology. The information processing system shown in the figure is provided with a host computer 100, a memory controller 200, and a memory 300. The host computer 100 inputs and outputs data to and from the memory 300 through the memory controller 200. The host computer 100 is provided with a processor 110 and a host interface 109. The processor 110 controls overall operations of the host computer 100. The host interface 109 is an interface that communicates with the memory controller 200. The input and output of the data by the host computer 100 are performed by issuing a command to the memory controller 200 through a signal line 101. When the data is written in the memory 300, a write command is issued, and data to be written is output to the memory controller 200. When the data is read from the memory 300, a read command is issued to the memory controller 200. After that, the data read from the memory 300 is transferred from the memory controller 200 to the host computer 100, and terminates the read.

The memory controller 200 controls the memory 300. The memory controller 200 is provided with a host interface 209, a processing unit 207, a memory interface 208. The host interface 209 communicates with the host computer 100. The processing unit 207 performs processing on the basis of a command output from the host computer 100. Specifically, processing of coding and decoding data is performed, and a request that requests the data to be written or read is created and issued to the memory 300. It should be noted that the request is output through a signal line 201. The memory interface 208 communicates with the memory 300.

The memory 300 stores data. The memory 300 is provided with a memory interface 309, a memory device control unit 307, and a memory cell array 308. The memory interface 309 communicates with the memory controller 200. The memory device control unit 307 controls the memory 300 on the basis of the request issued from the memory controller 200. The specific content of the control will be described below. the memory cell array 308 stores data and is provided with a plurality of memory cells. As the memory cell, a nonvolatile memory, for example, a ReRAM (resistance random access memory) can be used. It should be noted that writing and reading data are performed on a page basis. The page has a size of 256 bytes, for example. It should be noted that, the memory 300 is an example of a nonvolatile memory described in the claims.

[Configuration of Memory Controller]

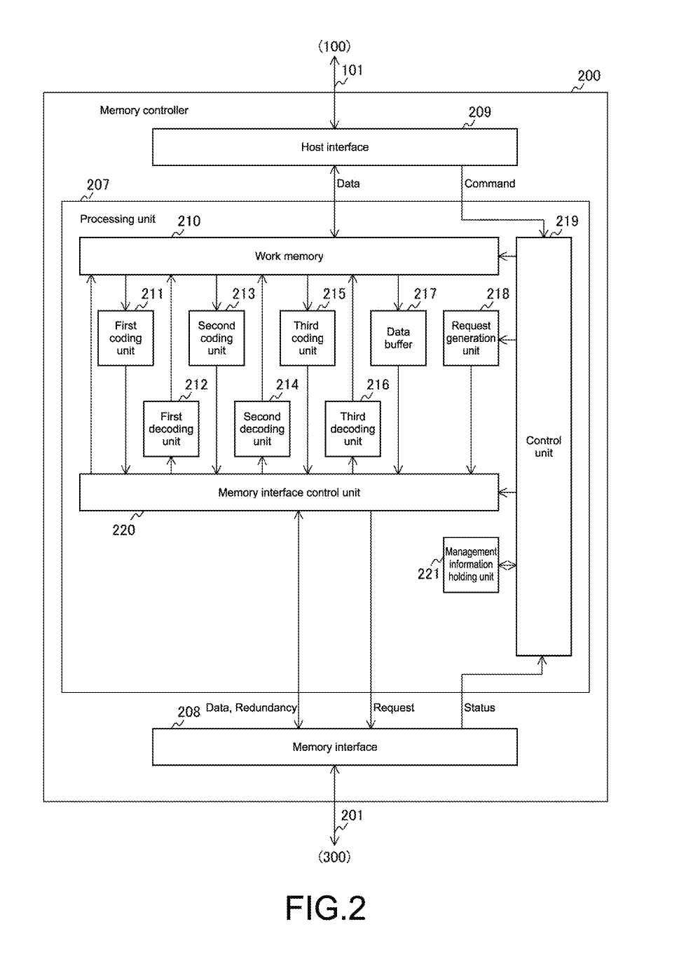

FIG. 2 is a diagram showing a configuration example of a memory controller according to the first embodiment of the present technology. The host interface 209 shown in the figure transfers a command issued from the host computer 100 to a control unit 219 in the processing unit 207. On the other hand, for data transmitted with the host computer 100, a bidirectional transfer is performed with a work memory 210 in the processing unit 207. The memory interface 208 shown in FIG. 2 transfers a request output from a memory interface control unit 220 in the processing unit 207 to the memory 300, and transfers a status output from the memory 300 to the control unit 219 in the processing unit 207. On the other hand, for data transmitted with the memory 300, a bidirectional transfer is performed with the memory interface control unit 220 in the processing unit 207. Here, the status means information that indicates a success or a failure of a write in the memory 300. Further, the status may include information indicating that the memory 300 is performing processing.

The processing unit 207 shown in FIG. 2 is provided with the work memory 210, a first coding unit 211, a first decoding unit 212, a second coding unit 213, a second decoding unit 214, a third coding unit 215, and a third decoding unit 216. Further, the processing unit 207 is provided with a data buffer 217, a request generation unit 218, the control unit 219, the memory interface control unit 220, and a management information holding unit 221. The work memory 210 holds data. The data includes data or the like output from the host computer 100, the memory 300, the first decoding unit 212, the second decoding unit 214, and the third decoding unit 216. Further, the work memory 210 has a function of allocating the data output from the host computer 100 to the first coding unit 211, the second coding unit 213, the third coding unit 215, or the data buffer 217. As the work memory 210, for example, an SRAM or a DRAM can be used.

The first coding unit 211 generates a redundancy (referred to as page redundancy, hereinafter) of page data as page-basis data. The second coding unit 213 generates a redundancy (referred to as expansion redundancy, hereinafter) of expansion data including a plurality of pages. The third coding unit 215 generates a redundancy (referred to as composite redundancy, hereinafter) of a code word block including a plurality of page code words. Here, the page code word indicates a code corresponding to page data, and is constituted of page data and a page redundancy. The first decoding unit 212 performs error detection and error correction of page data included in the page code word by the page redundancy included in the page code word. The second decoding unit 214 performs error detection and error correction of expansion data included in the expansion code word by the expansion redundancy included in the expansion code word. Here, the expansion code word indicates a code word corresponding to expansion data, and is constituted of expansion data and an expansion redundancy. The third decoding unit 216 performs error detection and error correction of a code word block included in a composite code word by the composite redundancy included in the composite code word. Here, the composite code word indicates the code word corresponding to the code word block, and is constituted of the code word block and the composite redundancy. Those will be described in detail later.

The data buffer 217 temporarily holds data to be transferred to the memory 300. As the data buffer, for example, an SRAM or a DRAM can be used. The request generation unit 218 generates a request. The request will be described in detail later.

The memory interface control unit 220 controls the transfer of the data and the request. Specifically, at a time when the request and the data are transferred to the memory 300, the request generated by the request generation unit 218 and the data output from the data buffer 217 are transferred to the memory 300. Further, the redundancy generated by the first coding unit 211, the second coding unit 213, or the third coding unit 215 is selected and transferred to the memory 300. Conversely, at a time when the data, the redundancy, and the status output from the memory 300 are transferred, the first decoding unit 212, the second decoding unit 214, or the third decoding unit 216 is selected, and the data and the redundancy are transferred. Further, the status is transferred to the control unit 219.

The control unit 219 interprets the command issued from the host computer 100 and controls units of the memory controller 200. Specifically, the control of transfer in the work memory 210 and the memory interface control unit 220, the control of generation of the request in the request generation unit 218, and the control of the management information holding unit 221 described above are performed. For the control unit 219, a control circuit provided with a processor can be used. The management information holding unit 221 holds the management information. As the management information holding unit 221, for example, an SRAM or a DRAM can be used. Here, the management information refers to information other than data, for example, address conversion information that indicates a corresponding relationship between a logical address specified by the host computer 100 and a physical address in the memory 300.

It should be noted that the first coding unit 211 is an example of a first coding unit described in the claims. The first decoding unit 212 is an example of a first decoding unit described in the claims. The second coding unit 213 is an example of a second coding unit described in the claims. The second decoding unit 214 is an example of a second decoding unit described in the claims. The third coding unit 215 is an example of a third coding unit described in the claims. The third decoding unit 216 is an example of a third decoding unit described in the claims.

[Configuration of Memory]

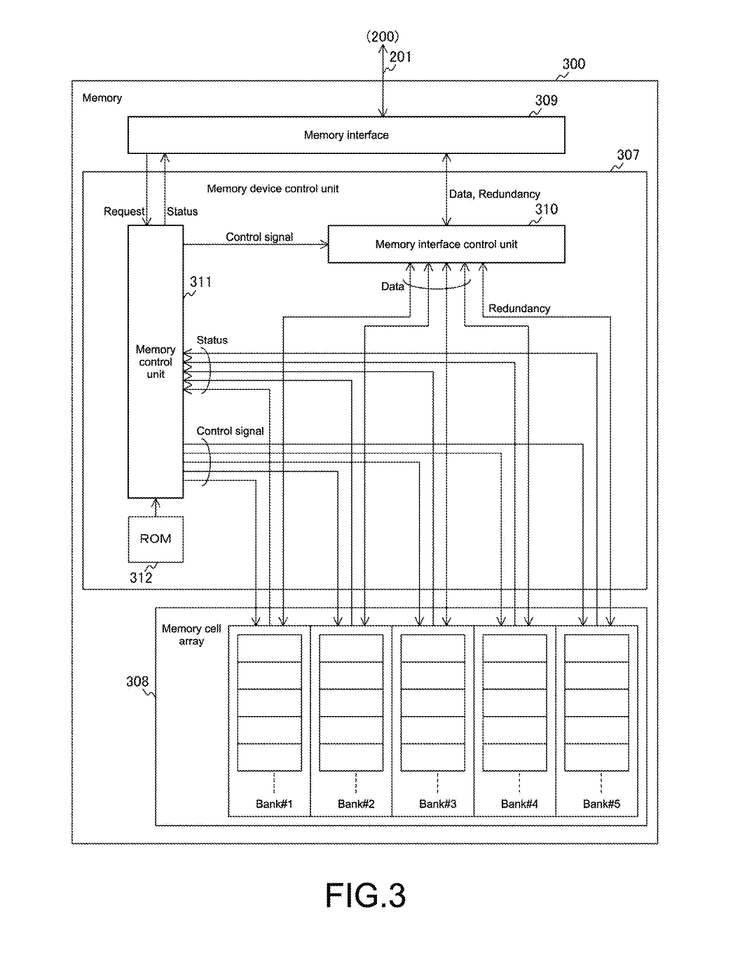

FIG. 3 is a diagram showing a configuration example of a memory according to the first embodiment of the present technology. A memory interface 309 shown in the figure transfers a request issued from the memory controller 200 to a memory control unit 311 in the memory device control unit 307. Further, the status output from the memory control unit 311 is transferred to the memory controller 200. The data and the redundancy are subjected to a bidirectional transfer with a memory interface control unit 310 in the memory device control unit 307.

The memory device control unit 307 shown in FIG. 3 is provided with the memory interface control unit 310, the memory control unit 311, and a ROM 312. The memory interface control unit 310 selects a plurality of banks in the memory cell array 308 and performs bidirectional transfer of the data and the redundancy with the bank. The memory control unit 311 interprets the request issued from the memory controller 200 and controls the memory interface control unit 310 and the memory cell array 308. The memory control unit 311 outputs a control signal to the memory interface control unit and the memory cell array 308, to control those. Further, on the basis of the status output from the memory cell array 308, it is determined whether a write of data or the like succeeds or fails, and a result of the determination is output to the memory controller 200 as the status. The determination is performed as follows. The banks in the memory cell array each output a result of a write to the memory control unit 311 as the status. In the case where all the statuses show successes, the memory control unit 311 determines that the write succeeds. On the other hand, if any one of the statuses output from the banks show a failure, the memory control unit 311 determines that the write fails.

The ROM 312 holds bank number conversion information that indicates a correspondence between the requests output from the memory controller 200 and the banks in the memory cell array 308 as targets of the write or read of data or the like. For the ROM 312, a PROM can be used.

The memory cell array 308 shown in FIG. 3 is constituted of a plurality of banks, and the banks are each provided with a plurality of memory cells accessible on a page basis. Further, the banks can independently write or read data. The banks are each provided with a data line for transferring data or redundancy bidirectionally, a status line for outputting the status, and a control signal line for inputting a control signal. The control signal includes an instruction for giving an instruction of transferring, writing, or reading data, and a page address. In the example shown in FIG. 3, the memory cell array 308 is constituted of five banks.

[Configuration of Memory Cell Array]

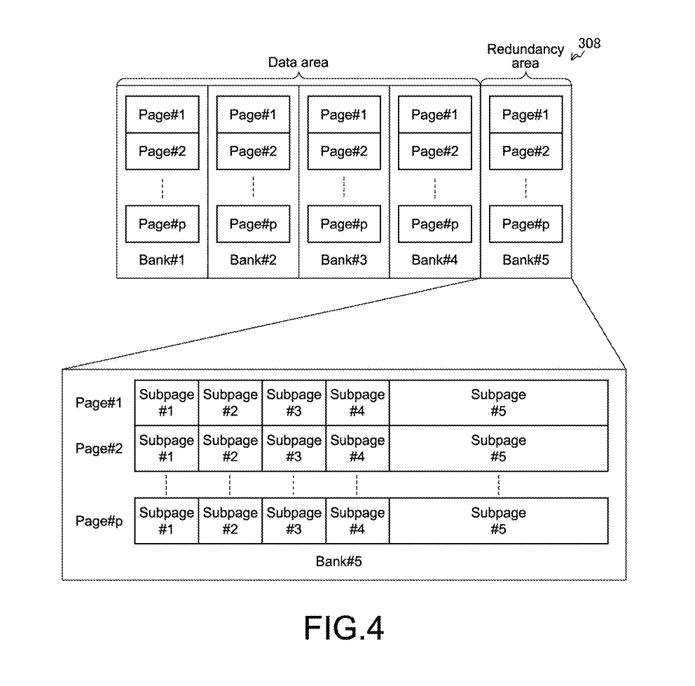

FIG. 4 is a diagram showing a configuration example of the memory cell array according to the first embodiment of the present technology. The memory cell array 308 shown in the figure is provided with a data area and a redundancy area. To the data area, banks #1 to #4 are assigned, and to the redundancy area, a bank #5 is assigned. Further, the banks are each provided with memory cells of p pages. The memory cell of the bank #5 assigned to the redundancy area is further constituted of five subpages, and the redundancy is stored in a predetermined subpage depending on kinds of redundancy to be described later. It should be noted that, the control signal in the bank #5 includes subpage numbers in addition to the instruction and the page address described above.

[Kinds and Configuration of Code Word]

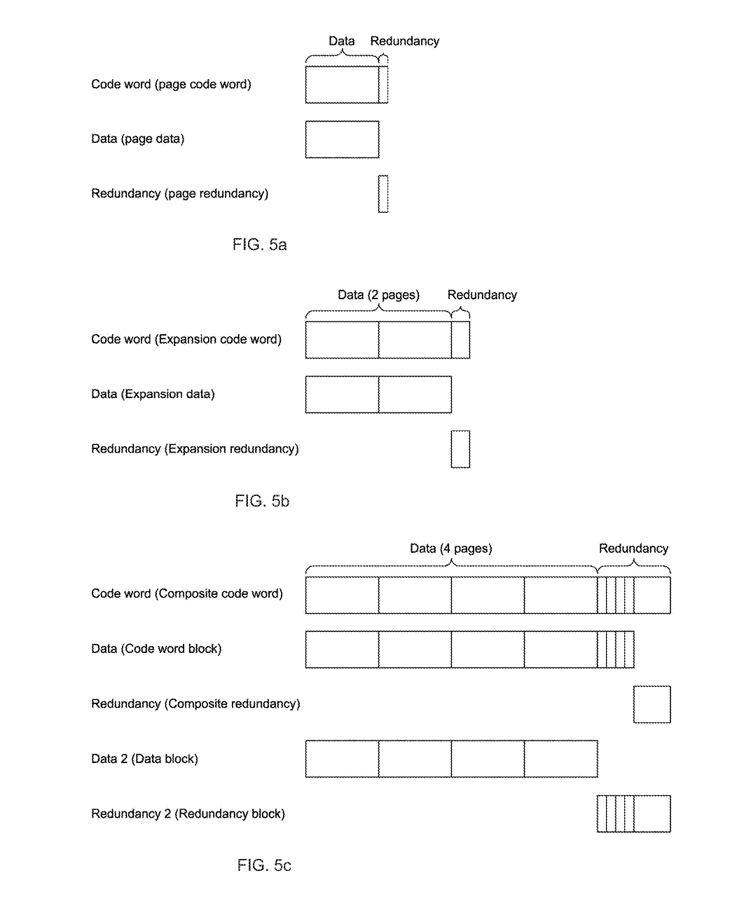

FIGS. 5a, 5b and 5c are a diagrams showing a configuration example of a code word according to the first embodiment of the present technology. In the first embodiment of the present technology, three kinds of redundancies of a page redundancy, an expansion redundancy, and a decoding redundancy. FIG. 5a represents a relationship among the code word, data, and redundancy in the case of the page redundancy. In the page code word, the redundancy (page redundancy) is generated for page-basis data (page data). The page redundancy includes a parity of the page data. For the parity, for example, it is possible to use a parity generated by using a hamming code. At a time when the page code word is stored in the memory cell array described with reference to FIG. 4, the page data is stored in the memory cell of the bank assigned to the data area, and the page redundancy is stored in the subpage of the same page address in the bank assigned to the redundancy area. For example, the page data is stored in the memory cell of a page #1 of the bank #1, and the page redundancy is stored in the memory cell of the subpage #1 and the page #1 of the bank #5.

FIG. 5b represents a relationship among the code word, data, and redundancy in the case of the expansion code word. The data shown in the figure has the size of two pages. That is, in the expansion code word, for the data (expansion data) having the size of two pages, a redundancy (expansion redundancy) is generated. Further, for the parity included in the expansion redundancy, a parity generated by the same system as the page redundancy is used. For the expansion code word, the data and the redundancy have a double size of the page code word. Therefore, at a time when the expansion code word is stored in the memory cell array, the expansion data is stored in the memory cells of two banks in the data area, and the page redundancy is stored in the two subpages in the bank in the redundancy area. For example, the page data is stored in the memory cell of the page #1 of the bank #1 and in the memory cell of the page #1 of the bank #2, and the page redundancy is stored in the memory cells of the subpage #1 and subpage #2 of the page #1 in the bank S.

FIG. 5c represents a relationship among the code word, data, and redundancy in the case of the composite code word. The data in the figure is constituted of four page code words (code word blocks). That is, in the composite code word, a redundancy (composite redundancy) is generated for the code word block. It should be noted that four pieces of page data included in the code word block are referred to as data blocks, and four page redundancies and composite redundancies included in the code word block are referred to as redundancy blocks. Those are treated as data 2 and redundancy 2, respectively, in the request to be described later. For the parity included in the composite redundancy, a parity generated by using the same system as or a different system from the page redundancy, for example, by using an LDPC (Low Density Parity Check) code. At a time when a composite code word is stored in the memory cell array, the data block is stored in the bank of the data area, and the redundancy block is stored in the bank of the redundancy area. For example, the data block is stored in the memory cells of the page #1 of the banks #1 to #4. Four page redundancies included in the redundancy block is stored in the subpages #1 to #4 of the page #1 of the bank #5, and the composite redundancy is stored in the subpage #5 of the page #1 of the bank #5.

As described above, the expansion data is set to have a double size of the page data, and the data block of the composite redundancy is set to have a double size of the expansion data. The number of pieces of page data included in the data block and the number of banks included in the data area in the memory cell array 308 are set to be the same value. In a similar way, the number of redundancies included in the redundancy block of the composite redundancy and the number of subpages of the redundancy area of the bank #5 in the memory cell array 308 are set to be the same value. As a result, with respect to the memory cell accessible by one page address, four page code words, two expansion code words, or one composite code can be stored. It should be noted that, the subpages #1 to #4 of the bank #5 of the redundancy area is set to have the same size as the page redundancy, and the subpage #5 is set to have the same size as the composite redundancy. As described above, the sizes of the pages are set to be a multiple or an aliquot of the data length, and the sizes of the subpages are set to be the same as the length of the redundancy or be an aliquot thereof, with the result that it is possible to improve a memory cell use efficiency at a time when the data or the like is recorded.

However, the relationship among the page code word, the expansion code word, and the composite code word and the configuration of the memory cell array described with reference to FIG. 4 are not limited to the above. For example, the subpages included in the bank #5 of the redundancy area in FIG. 4 may be set to have the same size, and in the case of storing the composite redundancy, as in the case of the expansion redundancy, the redundancy may be stored in a plurality of subpages. In this case, instead of the subpage #5 shown in the FIG. 4, subpages #5 to #8 having the same size as the subpages #1 to #4 are disposed, and the composite redundancy is stored therein.

[Configuration of Redundancy]

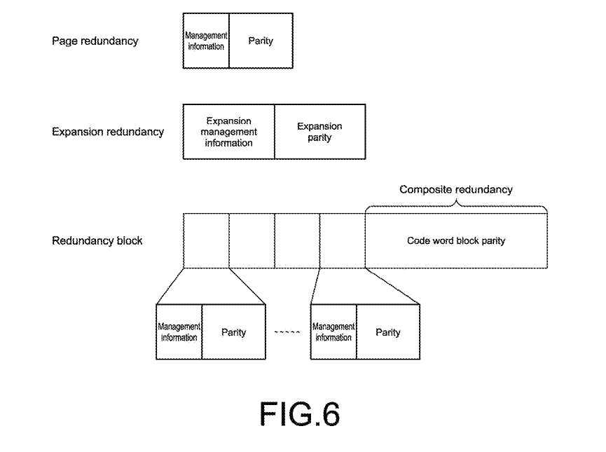

FIG. 6 is a diagram showing a configuration example of the redundancy according to the first embodiment of the present technology. The figure shows the configuration of the redundancy in each case of the page redundancy, the expansion redundancy, and the redundancy block. In the first embodiment of the present technology, the page redundancy is constituted of management information related to the page data and the parity for performing the error detection and error correction for the page data and management information. The expansion redundancy is constituted of expansion management information, which is the management information related to the expansion data and an expansion parity for performing the error detection and error correction for the expansion data and expansion management information. On the other hand, the composite redundancy of the redundancy block is configured only by a code word block parity, which is the parity of the code word block.

[Operations of Coding Unit and Decoding Unit]

The first coding unit 211 described with reference to FIG. 2 generates the parity from the input page data and the management information related to the page data and outputs the management information thereto as the page redundancy. Further, the first decoding unit 212 decodes the input page code word and outputs the page data and extracts the management information from the page code word and outputs the information. The second coding unit 213 generates the expansion parity from the input two-page data (expansion data) and the management information (expansion management information) related to the expansion data, to be output as the expansion redundancy with the expansion management information added thereto. Further, the second decoding unit 214 decodes the input expansion code word and outputs the expansion data. Furthermore, the second decoding unit 214 extracts the expansion management information from the expansion code word and outputs the information. The third coding unit 215 generates, from the input four code words (code word blocks), the parity (code word block parity) and outputs the parity as the composite redundancy. Further, the third decoding unit 216 decodes the input composite code word and outputs four code words (code word blocks).

[Management Information]

As described above, in the first embodiment of the present technology, address conversion information can be the management information. The management information is stored in a predetermined area of the memory 300, is read by the memory controller 200 from the memory 300 at a time of activation, and is transferred to the management information holding unit 221. However, due to an accident such as a power supply abnormality, the management information may be broken down. In this case, it is necessary to reproduce the management information. In the first embodiment of the present technology, the redundancy including the parity of the data and part of the management information related to the data is generated, and is stored in the redundancy area of the memory cell array 308. Then, at a time when the management information is reproduced, the management information stored in the redundancy area is read, and the original management information is reproduced. The control is performed by the control unit 219.

[Configuration of Request]

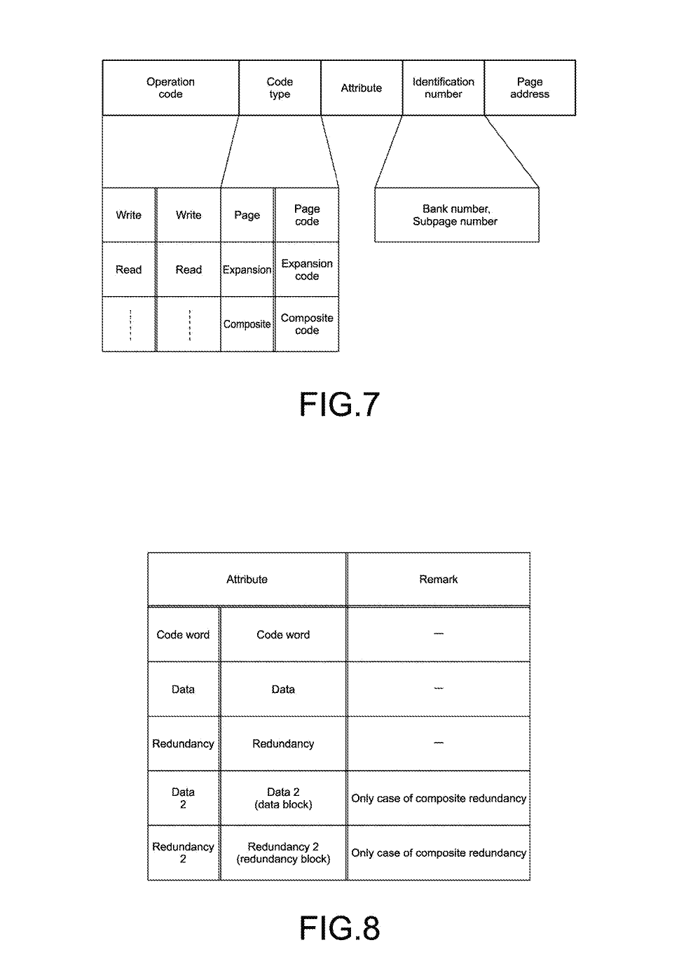

FIG. 7 is a diagram showing a configuration example of the request according to the first embodiment of the present technology. The figure represents the configuration of the request generated by the request generation unit 218 described with reference to FIG. 2. On the basis of a command output from the host computer 100, the request generation unit 218 generates the request for requesting the memory 300 to perform writing or reading for the various kinds of code words, data, and redundancies described above. As shown in FIG. 7, the request is constituted of five fields in which identifiers indicating an operation code, a code type, an attribute, an identification number, and a page address are disposed, respectively. The operation code represents a kind of the request. In FIG. 7, the operation code indicating writing and reading is shown. The code type represents a kind of the code. In the first embodiment of the present technology, one of a page code, an expansion code, and a composite code is specified. The attribute will be described later. The identification number represents numbers of banks or subpages to be subjected to the write or read. In a similar way, the page address represents a page address to be subjected to the write or read.

[Configuration of Attribute Identifier]

FIG. 8 is a diagram showing an example of attributes of the request according to the first embodiment of the present technology. The attributes represent kinds of operand in the request. The attributes of the code word, data, redundancy, data 2, and redundancy 2 shown in the figure correspond to the code word and the like shown in FIGS. 5a, 5b and 5c on the one-to-one basis. On the basis of the attributes and code types mentioned above, it is possible to specify data or the like to be subjected to the write or read.

[Write and Read Process by Request]

The request as described above is generated and issued from the memory controller 200 to the memory 300. The memory control unit 311 described with reference to FIG. 3 interprets the request and controls the memory interface control unit 310 and the memory cell array 308. While using the case where the kind of the request is “Write”, the code type is “page code”, the attribute is “code word”, and the identification number is “1” as an example, a control operation of the memory control unit 311 will be described. First, the memory control unit 311 controls the memory interface control unit 310 in such a manner that the page data out of the page code word output from the memory controller 200 is transferred to the bank #1. Further, as a control signal of the bank, an instruction of giving an instruction to perform data transfer and a page address specified by the page address of the request are output. After that, an instruction of giving an instruction to perform a write is output to the bank. Subsequently, the memory control unit 311 controls the memory interface control unit 310 in such a manner that the page redundancy out of the page code word output from the memory controller 200 is transferred to the subpage #1 of the bank #5 as a redundancy bank. A data transfer instruction and a write instruction are output in a similar way.

As described above, the code word is written in the data area and the redundancy area of the same page address. Further, the banks of the data area and the subpages included in the bank of the redundancy area to which the same identification numbers are assigned are treated as a pair, and the data and the redundancy belonging to the same code word are stored. Similarly, in the case where the code type is “expansion code”, the banks of the data area and the subpages included in the bank #5 of the redundancy area to which the same identification numbers are assigned are treated as a pair, and by the identification number specified by the request, a subpage number is uniquely determined. For example, in the case where the code type is “expansion code”, the attribute is “code word”, and the identification number is “1”, the expansion data is written in the banks #1 and #2, and the expansion redundancy is written in the subpages #1 and #2 of the bank #5. Those are performed on the basis of the bank number conversion information stored in the ROM 312.

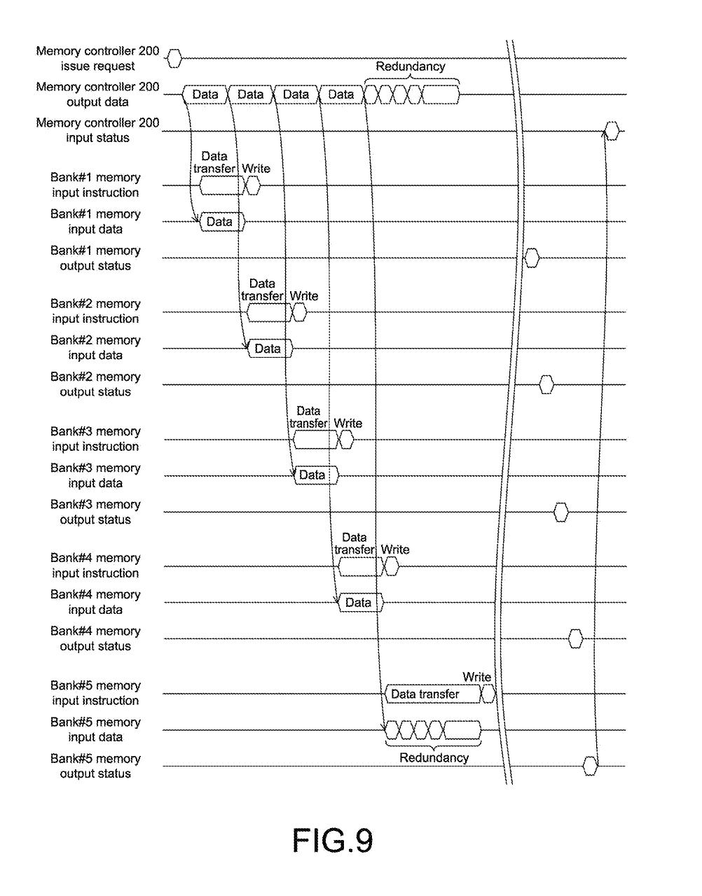

Next, the case where the composite redundancy is specified is cited as an example, and processing of the request in the memory controller 200 and the memory 300 will be described with reference to FIGS. 9 to 18.

FIG. 9 is a diagram for explaining processing of the request (write of composite code word) according to the first embodiment of the present technology. The figure shows a relationship among a request output, a data output, and a status input of the memory controller 200 and an instruction input, a data input, and a status output in each bank of the memory cell array 308.

First, processing in the memory controller 200 will be described. It should be noted that the assumption is made that four page code words (code word blocks) output from the host computer 100 are stored in the work memory 210. The control unit 219 controls the work memory 210 and transfers the code word blocks to the third coding unit 215 and the data buffer 217. The third coding unit 215 generates the composite redundancy. Further, the control unit 219 causes the request generation unit 218 to generate a request. During the time, the data buffer 217 holds the code word blocks. After that, the generated request and composite redundancy and the code word blocks held in the data buffer 217 are collected in the memory interface control unit 220 and output to the memory 300 through the memory interface 208. The control unit 219 performs this control. As a result, the request is issued from the memory controller 200, and then data (data blocks) of four pages, which is write data, and the redundancy blocks are output in order.

Subsequently, processing in the memory 300 will be described. The request issued from the memory controller 200 is transferred to the memory control unit 311. On the basis of the request, the memory control unit 311 controls the memory interface control unit 310 so as to transfer the data blocks and the redundancy blocks output from the memory controller 200 to predetermined banks of the memory cell array 308. That is, the first data of the data blocks is transferred to the bank #1. After that, the second data, the third data, and the last data are transferred to the bank #2, the bank #3, and the bank #4, respectively. Further, the redundancy blocks are transferred to the bank #5. At the time of the transfer, a data transfer instruction is output from the memory control unit 311 to the banks, and then a write instruction is output. When the write process is terminated, the banks output statuses. The memory control unit 311 takes in the statuses, determines writing results to generate statuses, and outputs the statuses to the memory controller 200.

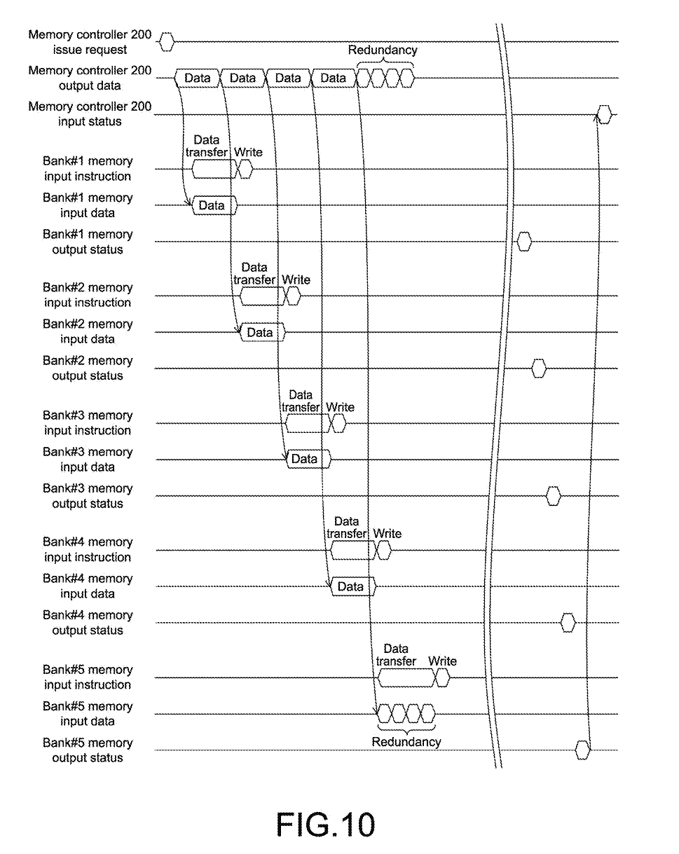

FIG. 10 is a diagram for explaining processing of the request (write of code word block) according to the first embodiment of the present technology. From the memory controller 200, the data blocks and four page redundancies are output in order and transferred to the banks of the memory cell array 308. The processing is different from the processing explained with reference to FIG. 9 in that the composite redundancy is not generated in the third coding unit 215, and writing the composite redundancy is not performed in the bank #5.

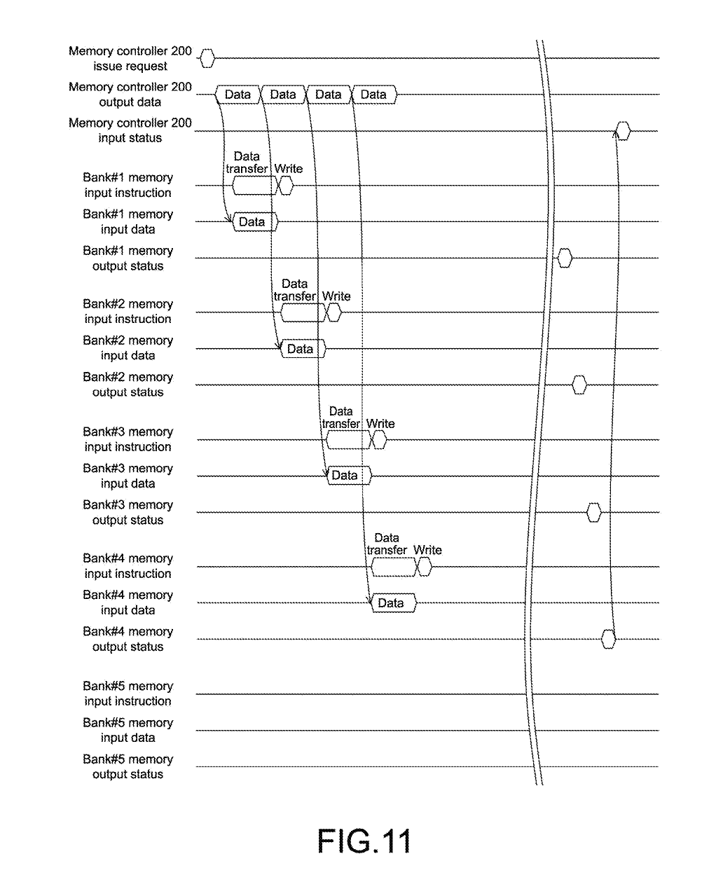

FIG. 11 is a diagram for explaining processing of the request (write of data block) according to the first embodiment of the present technology. From the memory controller 200, the data blocks are output and transferred to the banks #1 to #4 of the memory cell array 308. This processing is different from the processing explained with reference to FIG. 9 in that the composite redundancy is not generated in the third coding unit 215, only the data block is input to the data buffer 217, and writing the redundancy is not performed in the bank #5.

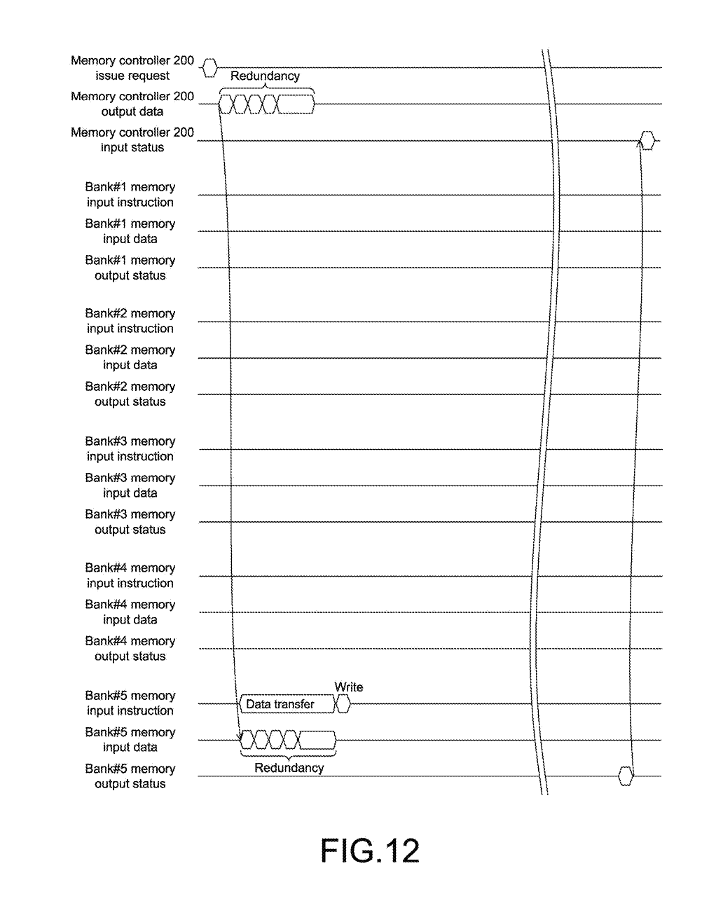

FIG. 12 is a diagram for explaining processing of the request (write of redundancy block) according to the first embodiment of the present technology. The redundancy block is output from the memory controller 200 and transferred to the bank #5 of the memory cell array 308. The processing is different from the processing explained with reference to FIG. 9 in that only the page redundancy is input to the data buffer 217, and writing data in the banks #1 to #4 is not performed.

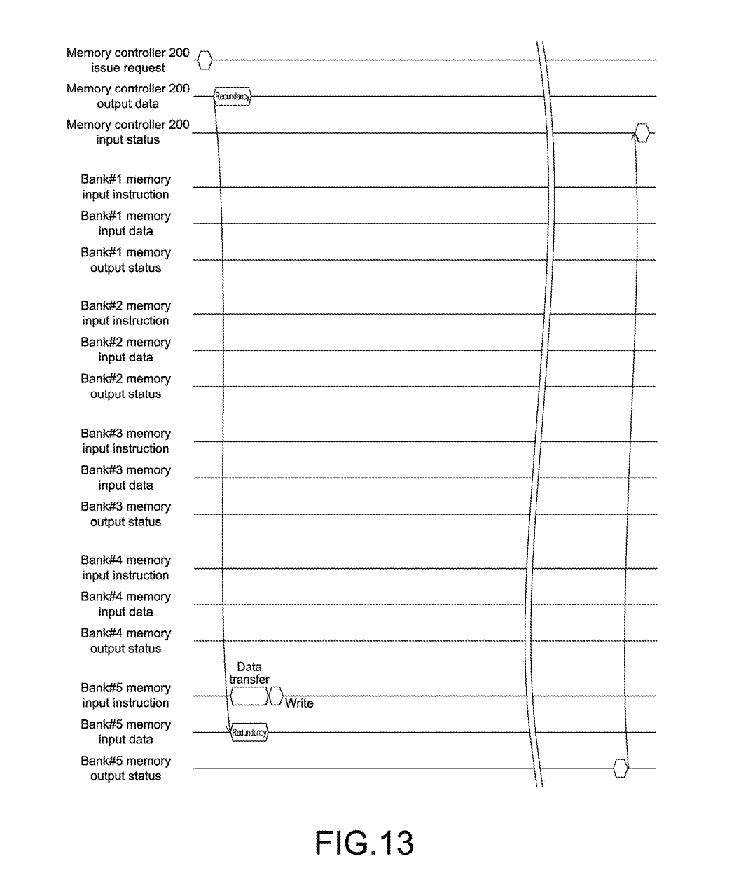

FIG. 13 is a diagram for explaining processing of the request (write of composite redundancy) according to the first embodiment of the present technology. The composite redundancy is output from the memory controller 200 and is transferred to the bank #5 of the memory cell array 308. The processing is different from the processing explained with reference to FIG. 9 in that inputting to and outputting from the data buffer 217 is not performed, writing data in the banks #1 to #4 is not performed, and writing page redundancy part in the bank #5 is not performed.

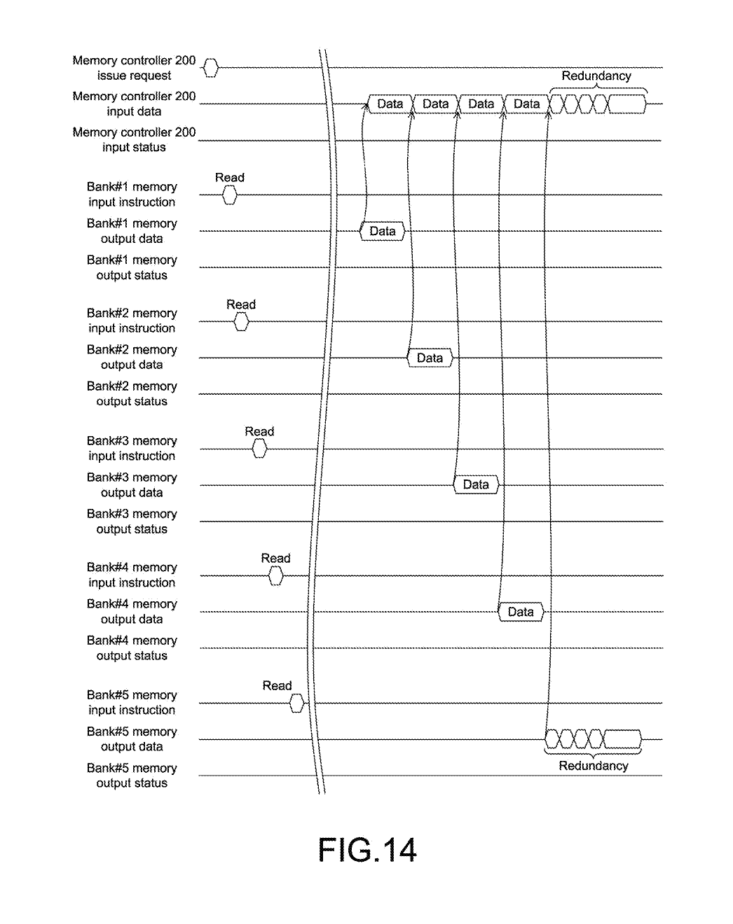

FIG. 14 is a diagram for explaining processing of the request (read of composite code word) according to the first embodiment of the present technology. First, processing in the memory 300 will be described. In a similar way to the write process described with reference to FIG. 9, when the request is issued from the memory controller 200, the memory control unit 311 interprets the request and outputs an instruction of giving an instruction to perform a read to the banks. At this time, to coincide timings of the data transfer, a timing when the instruction is output is shifted. After a read time in the memory cell elapses, from the banks #0 to #5, the data and the redundancy are output in order. The composite code word is constituted of those and is transferred to the memory controller 200. It should be noted that, at the time of reading, the status is not output.

Subsequently, processing in the memory controller 200 will be described. The composite code word output from the memory 300 is transferred to the memory interface control unit 220 through the memory interface 208. After that, the code word is transferred to the third decoding unit 216 and is decoded. The code word block thus obtained is output to the work memory 210. Finally, the code word block of the work memory 210 is transferred to the host computer, and then the processing is terminated. Those are controlled by the control unit 219.

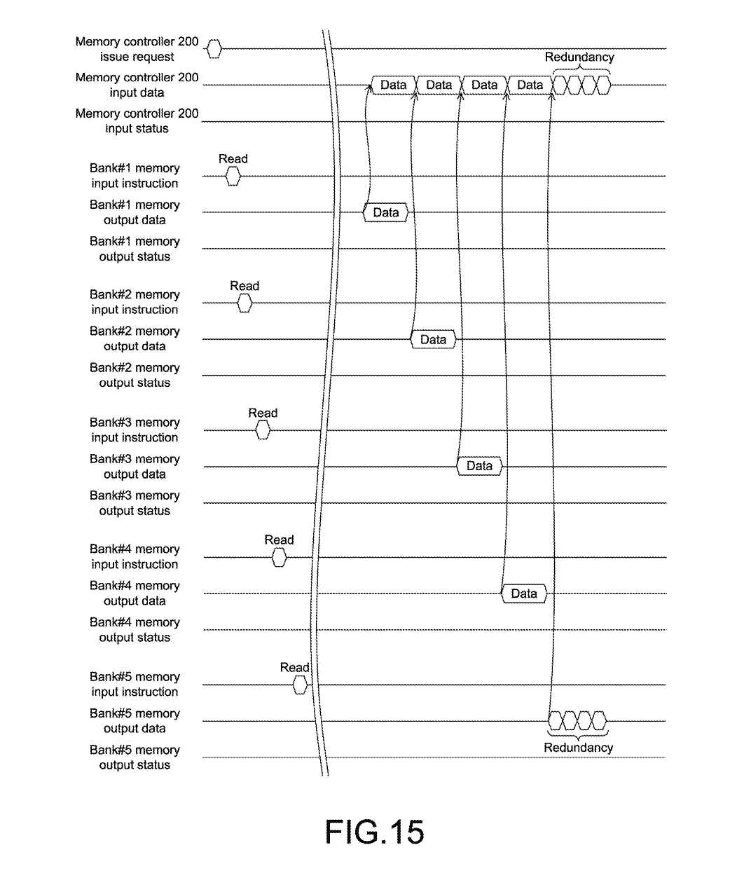

FIG. 15 is a diagram for explaining processing of the request (read of code word block) according to the first embodiment of the present technology. When a request is issued from the memory controller 200, the memory control unit 311 outputs an instruction to the banks to perform a read. After that, the data and redundancies output from the banks constitute the code word block, and this is transferred to the memory controller 200. The processing is different from the processing described with reference to FIG. 14 in that reading of the composite redundancy is not performed, the input and output relating to the third decoding unit 216 is not performed, and the code word block is transferred from the memory interface control unit 220 to the work memory 210.

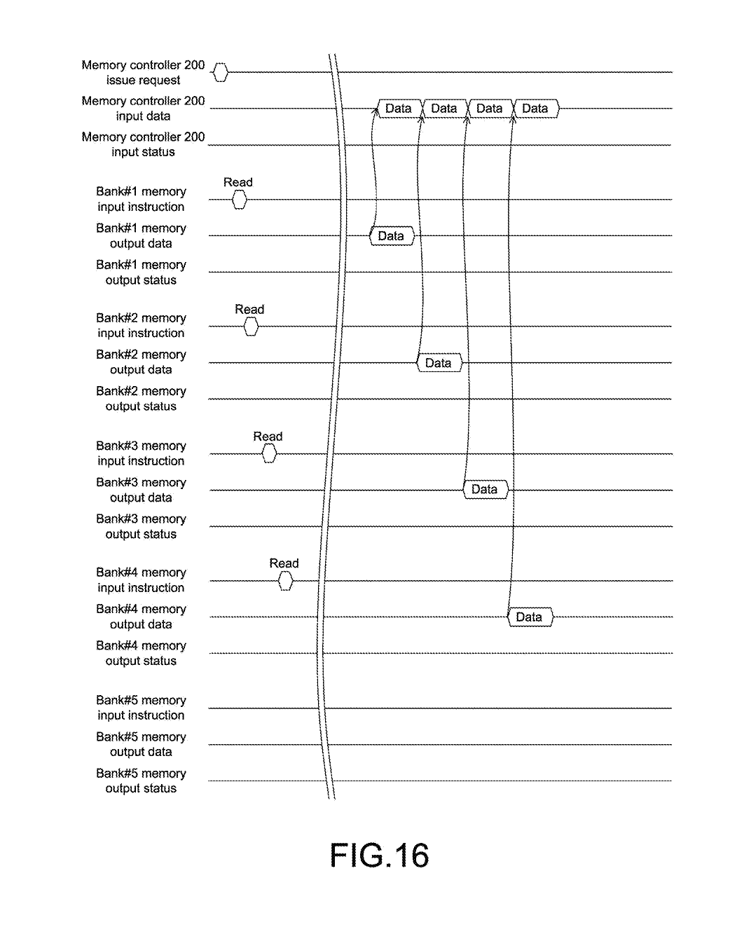

FIG. 16 is a diagram for explaining processing of the request (read of data block) according to the first embodiment of the present technology. When the request is issued from the memory controller 200, the memory control unit 311 outputs an instruction to the banks #1 to #4 to perform a read. After that, the data output from the banks constitutes the data block, and this is transferred to the memory controller 200. The processing is different from the processing described with reference to FIG. 14 in that reading of the redundancy is not performed, the input and output relating to the third decoding unit 216 is not performed, and the data block is transferred from the memory interface control unit 220 to the work memory 210.

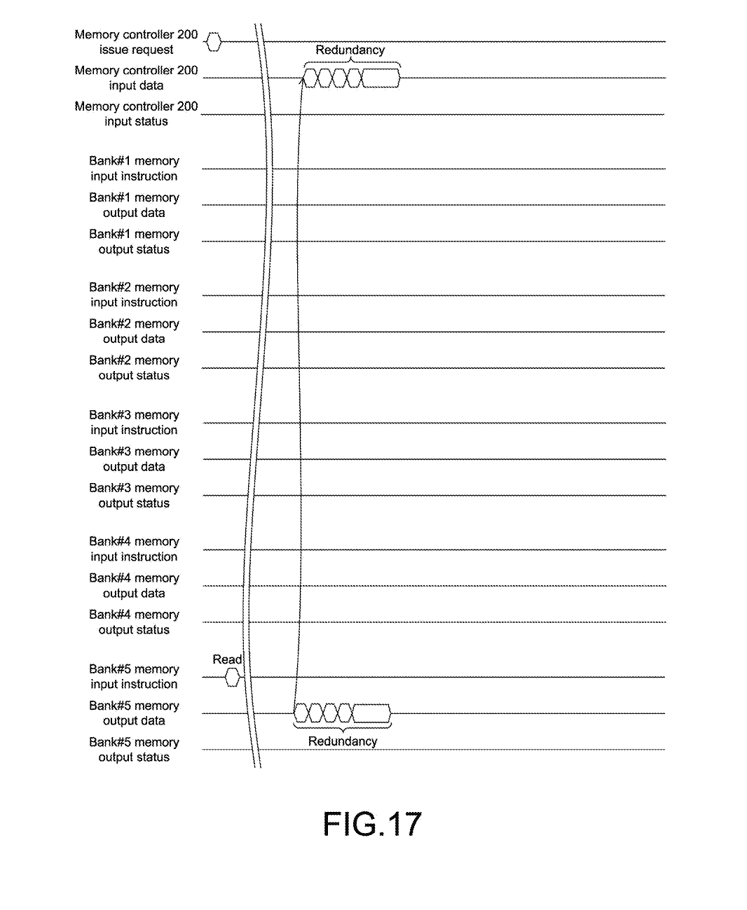

FIG. 17 is a diagram for explaining processing of the request (read of redundancy block) according to the first embodiment of the present technology. When the request is issued from the memory controller 200, the memory control unit 311 outputs an instruction to the bank #5 to perform a read. After that, the redundancy block output from the bank #5 is transferred to the memory controller 200. The processing is different from the processing described with reference to FIG. 14 in that reading of the data part is not performed, the input and output relating to the third decoding unit 216 is not performed, and the redundancy block is transferred from the memory interface control unit 220 to the work memory 210.

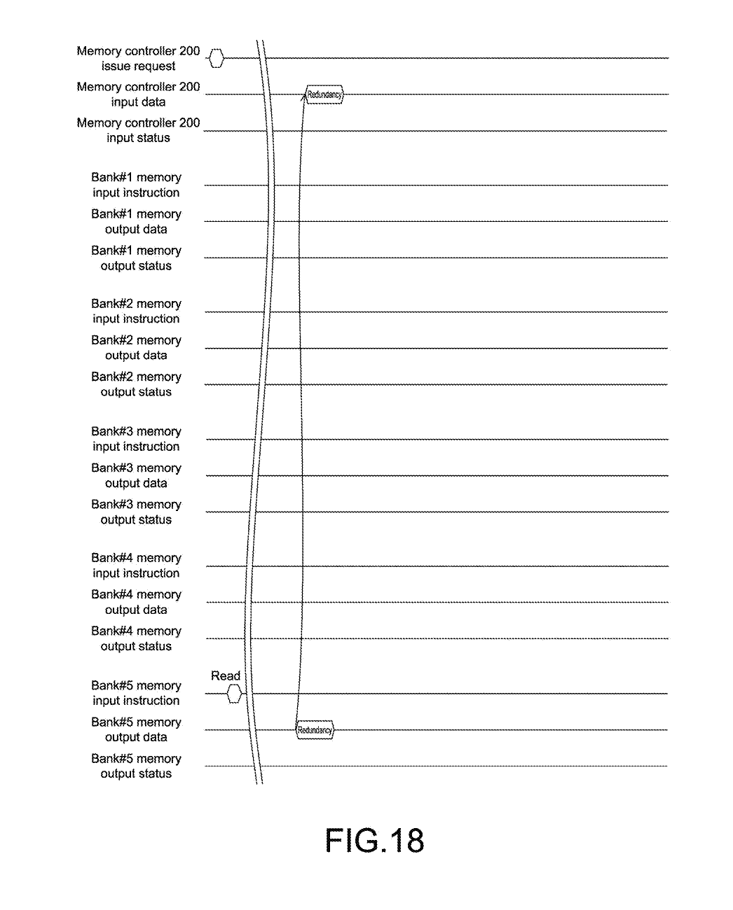

FIG. 18 is a diagram for explaining processing of the request (read of composite redundancy) according to the first embodiment of the present technology. When the request is issued from the memory controller 200, the memory control unit 311 outputs an instruction to the bank #5 to perform a read. After that, the composite redundancy output from the bank #5 is transferred to the memory controller 200. The processing is different from the processing described with reference to FIG. 14 in that the read of the data and page redundancy part is not performed, the input and output relating to the third decoding unit 216 is not performed, and the composite redundancy is transferred from the memory interface control unit 220 to the work memory 210.

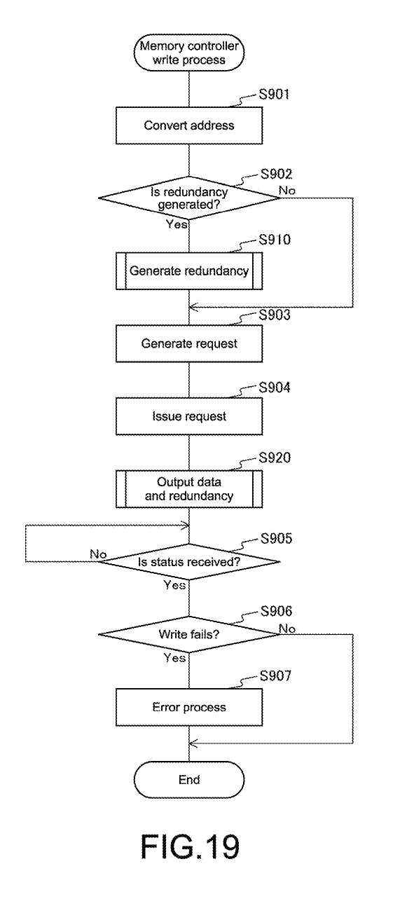

As described above, the memory controller 200 generates the requests and issued to the memory 300. After that, the memory controller 200 and the memory 300 transmit and receive the data and redundancies therebetween, to perform the write and read process. In view of this, with reference to FIGS. 19 to 29, a description will be given on the write and read process in the information processing system described with reference to FIG. 1. It should be noted that the description is given with processing in the memory controller 200 and processing in the memory 300 separated.

[Procedure of Write Process (Processing on Memory Controller Side)]

FIG. 19 is a flowchart showing an example of a procedure of a write process (memory controller) according to the first embodiment of the present technology. Upon reception of a write command from the host computer 100, the memory controller 200 starts the write process. First, on the basis of address conversion information of the management information, a logical address included in the command is converted to a physical address (Step S901). It should be noted that, in the first embodiment of the present technology, to the physical address, a page address and a bank number are corresponded. In the case where a command write target is the page code word, the expansion code word, the composite code word, the page redundancy, the expansion redundancy, the composite redundancy, or the redundancy block, the redundancy has to be generated (Step S902: Yes), so the redundancy is generated (Step S910). On the other hand, in the case where the command write target is the page data, the expansion data, the code word block, or the data block, the redundancy does not have to be generated (Step S902: No), so the process proceeds to the next without generating the redundancy.

Subsequently, the memory controller 200 generates a write request (Step S903). This is performed by the request generation unit 218 described with reference to FIG. 2. After that, the generated request is issued to the memory 300 (Step S904). Subsequently, the data and the redundancy which meet the request are output to the memory 300 (Step S920). As a result, in the memory 300, the write process is performed. The memory controller 200 awaits an output of the status from the memory 300 (Step S905). When the status is output (Step S905: Yes), it is determined whether a write failure exists or not on the basis of the status (Step S906). As a result, in the case of a write success (Step S906: No), the write process is terminated. On the other hand, in the case of a write failure (Step S906: Yes), an error process is performed (Step S907), and the write process is terminated. Here, as the error process, for example, it is possible to perform a process of notifying the host computer 100 of an abnormal termination.

[Procedure of Redundancy Generation Process (Process on Memory Controller Side)]

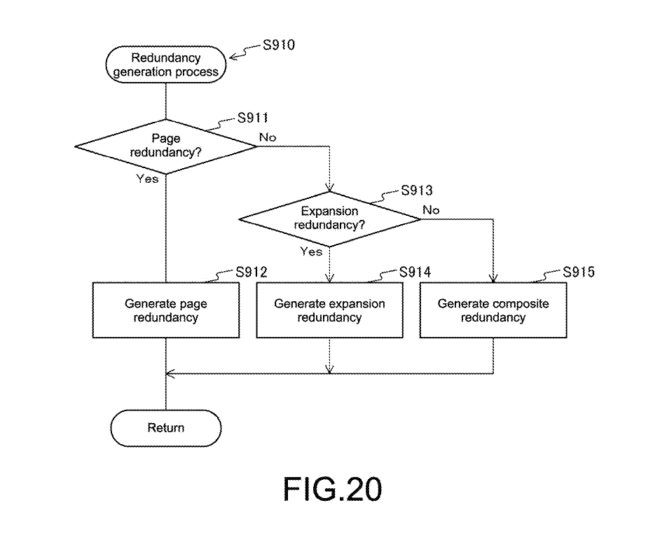

FIG. 20 is a flowchart showing an example of a procedure of a procedure (memory controller) of a redundancy generation process according to the first embodiment of the present technology. The memory controller 200 determines and generates a necessary redundancy on the basis of a command write target. In the case where the write target is the page code word or the page redundancy (Step S911: Yes), the memory controller 200 generates the page redundancy (Step S912). In the case where the write target is the expansion code word or the expansion redundancy (Step S911: No, and Step S913: Yes), the memory controller 200 generates the expansion redundancy (Step S914). In the case where the write target is the composite code word, the composite redundancy, or the redundancy block (Step S911: No, and Step S913: No), the memory controller 200 generates the composite redundancy (Step S915). The generation of the redundancies is performed by the first coding unit 211, the second coding unit 213, and the third coding unit 215 described with reference to FIG. 2. It should be noted that, in the first embodiment of the present technology, the page redundancy is constituted of the parity and the management information. The memory controller 200 generates the page redundancy from the page data and the management information related to this (Step S912). The same holds true for generation of the expansion redundancy (Step S914).

[Procedure of Data and Redundancy Output Process (Process on Memory Controller Side)]

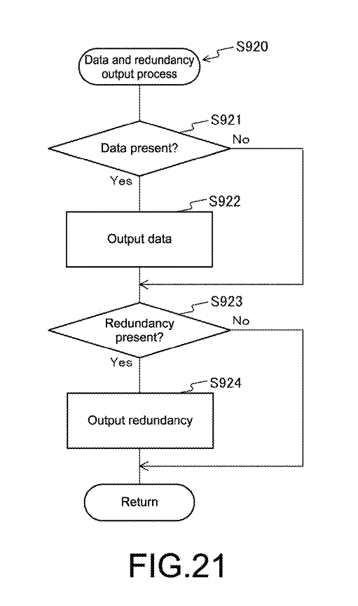

FIG. 21 is a flowchart showing an example of a procedure (memory controller) of a data and redundancy output process according to the first embodiment of the present technology. On the basis of a write target of a command, the memory controller 200 outputs the data or redundancy to the memory 300. First, in the case where the write target of the command is the page code word, the expansion code word, the composite code word, the page data, the expansion data, the code word block, or the data block, it is necessary to output the data (Step S921: Yes), the data is output (Step S922). In this case, on the basis of the write target of the command, the page data, the expansion data, or the data block is selected and output.

On the other hand, in the case where the write target of the command is the page redundancy, the expansion redundancy, the composite redundancy, or the redundancy block (Step S921: No), the data is not output, and the process proceeds to the next. Subsequently, in the case where the write target of the command is the page code word, the expansion code word, the composite code word, the page redundancy, the expansion redundancy, the code word block, the composite redundancy, or the redundancy block, it is necessary to output the redundancy (Step S923: Yes), so the redundancy is output (Step S924). In this case, on the basis of the write target of the command, the page redundancy, the expansion redundancy, the redundancy block, the redundancy part of the code word block, or the composite redundancy is selected and output. After that, the data and redundancy output process is terminated. On the other hand, in the case where the write target of the command is the page data, the expansion data, or the data block (Step S923: No), the redundancy is not output, the data and redundancy output process is terminated.

[Procedure of Write Process (Process on Memory Side)]

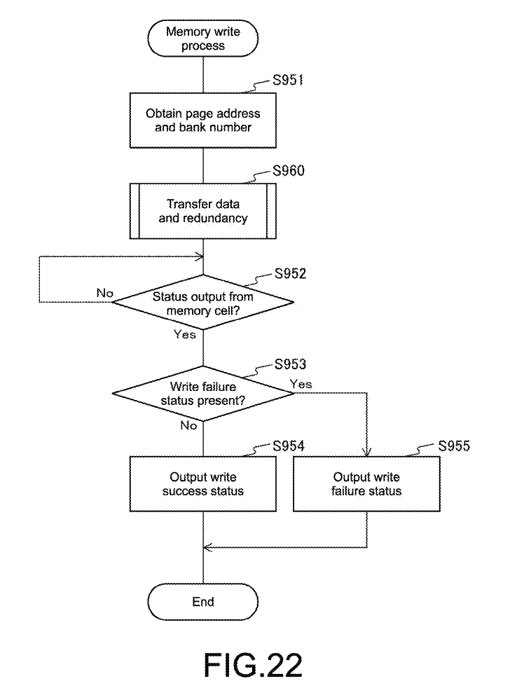

FIG. 22 is a flowchart showing an example of a procedure (memory) of a write process according to the first embodiment of the present technology. When a request of requesting writing from the memory controller 200 is issued, the memory 300 starts this process. First, the request is interpreted, a page address, a bank number, and a subpage number of a memory cell to which the writing is performed is obtained (Step S951). Subsequently, to the memory cells corresponding thereto, the data and the redundancy are transferred (Step S960). After that, outputting the status from the memory cell is awaited (Step S952). When the statuses are output from all the memory cells (Step S952: Yes), the memory 300 checks whether those statuses include a status indicating a write failure (Step S953). In the case where the statuses do not include the status indicating the write failure (Step S953: No), a status indicating a write success is output to the memory controller 200 (Step S954), and the write process is terminated. On the other hand, in the case where the statuses include the status indicating the write failure (Step S953: Yes), the status indicating the write failure is output to the memory controller 200 (Step S955), and the write process is terminated.

[Procedure of Data and Redundancy Transfer Process (Process on Memory Side)]

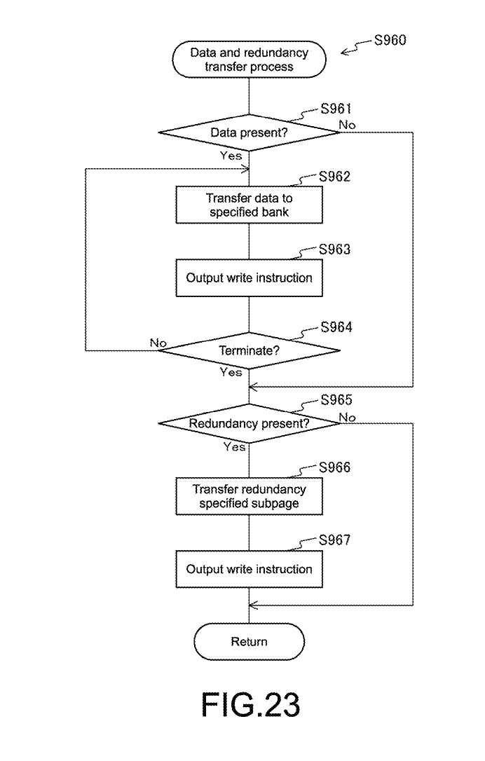

FIG. 23 is a flowchart showing an example of a procedure of a data and redundancy transfer process (memory) according to the first embodiment of the present technology. The memory 300 determines whether the write target of the request include data that is to be transferred or not (Step S961). In the case where the write target is the page code word, the expansion code word, the composite code word, the page data, the expansion data, the code word block, or the data block (Step S961: Yes), data is transferred to a specified bank (Step S962). At this time, to a control signal of the bank, the page address and the data transfer instruction are output. After the data is transferred, a write instruction is output (Step S963). When the transfer of all data is terminated (Step S964: Yes), the process proceeds to the next. In the case where the transfer of all data is not terminated (Step S964: No), the process from Step S962 is performed again. On the other hand, in the case where the write target of the request is the page redundancy, the expansion redundancy, the composite redundancy, or the redundancy block (Step S961: No), the data is not transferred, and the process proceeds to the next.

Subsequently, in the case where the write target of the request is the page code word, the expansion code word, the composite code word, the code word block composite redundancy, or the redundancy block, it is necessary to transfer the redundancy (Step S965: Yes), and the redundancy is transferred to the redundancy bank (Step S966). At this time, to the control signal of the redundancy bank, the page address, the subpage number, and the data transfer instruction are output. After the redundancy is transferred, the write instruction is output (Step S967). After that, the data and redundancy transfer process is terminated. On the other hand, in the case where the write target of the request is the page data, the expansion data, or the data block (Step S965: No), the redundancy transfer is not performed, and the data and redundancy transfer process is terminated.

[Procedure of Read Process (Process on Memory Controller Side)]

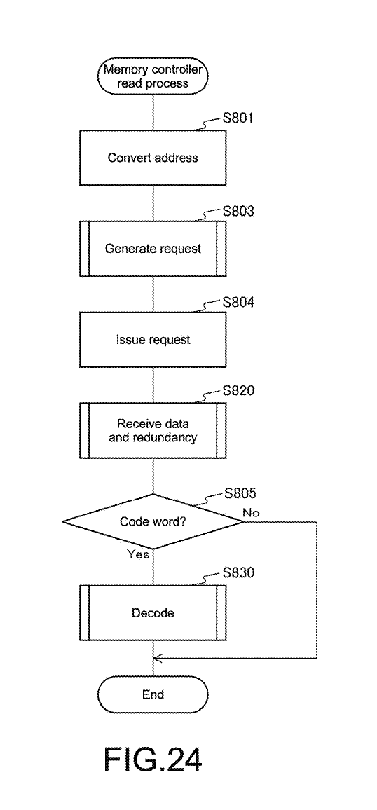

FIG. 24 is a flowchart showing an example of a procedure of a procedure of a read process (memory controller) according to the first embodiment of the present technology. Upon reception of a read command from the host computer 100, the memory controller 200 starts a read process. The memory controller 200 performs address conversion (Step S801) of converting a logical address to a physical address. Subsequently, a read request is generated (Step S803), and the request is issued (Step S804). After that, the data and the redundancy output from the memory 300 are received (Step S820). In the case where a read target of the request is the page code word, the expansion code word, or the composite code word, it is necessary to perform decoding (Step S805: Yes), so decoding is performed (Step S830), and the read process is terminated. The read target of the request is not the page code word, the expansion code word, or the composite code word (Step S805: No), decoding is not performed, and the read process is terminated.

[Procedure of Data and Redundancy Reception Process (Process on Memory Controller Side)]

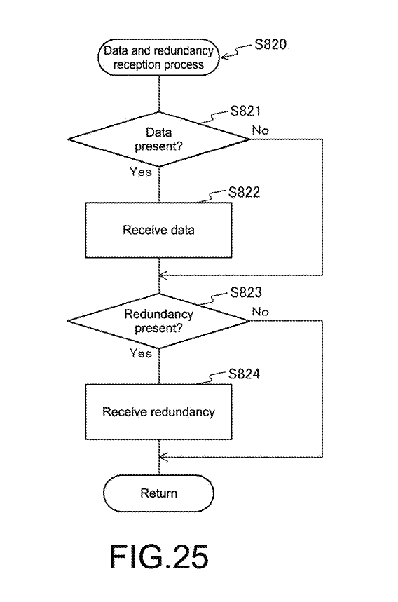

FIG. 25 is a flowchart showing an example of a procedure of a data and redundancy reception process (memory controller) according to the first embodiment of the present technology. On the basis of a command read target, the memory controller 200 receives the data or the redundancy from the memory 300. First, in the case where the read target of the command is the page code word, the expansion code word, the composite code word, the page data, the expansion data, the code word block, or the data block, it is necessary to receive the data (Step S821: Yes), so the data is received (Step S822). In this case, on the basis of the read target of the command, the page data, the expansion data, or the data block is received. On the other hand, in the case where the read target of the command is the page redundancy, the expansion redundancy, the composite redundancy, or the redundancy block (Step S821: No), the data is not received, and the process proceeds to the next. Subsequently, in the case where the read target of the command is the page code word, the expansion code word, the composite code word, the page redundancy, the expansion redundancy, the code word block, the composite redundancy, or the redundancy block, it is necessary to receive the redundancy (Step S823: Yes), and the redundancy is not received (Step S824). In this case, on the basis of the read target of the command, the page redundancy, the expansion redundancy, the redundancy block, the redundancy part of the code word block, or the composite redundancy is received. After that, the data and redundancy reception process is terminated. On the other hand, in the case where the read target of the command is the page data, the expansion data, or the data block (Step S823: No), the redundancy is not received, and the data and redundancy reception process is terminated.

[Procedure of Decoding Process (Process on Memory Controller Side)]

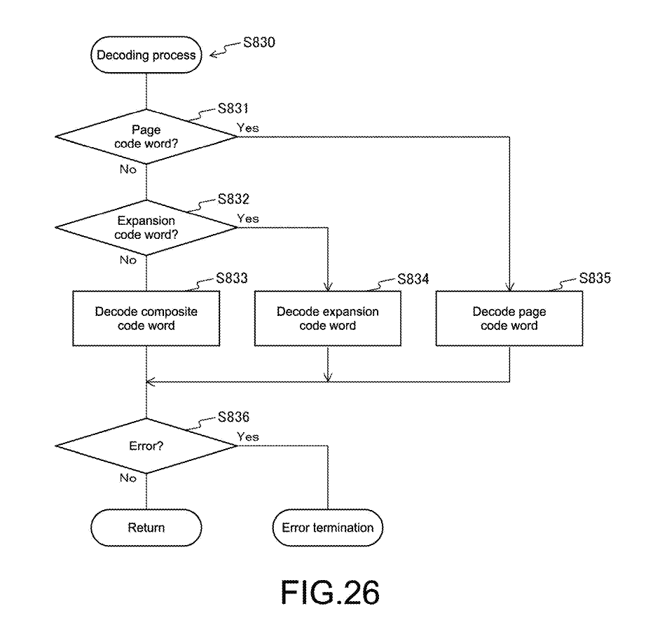

FIG. 26 is a flowchart showing an example of a procedure of a decoding process (memory controller) according to the first embodiment of the present technology. On the basis of a read target, the memory controller 200 selects a decoding process. In the case where the read target is the page code word (Step S831: Yes), decoding of the page code word is performed (Step S835). In the case where the read target is the expansion code word (Step S831: No and Step S832: Yes), decoding of the expansion code word is performed (Step S834). In the case where the read target is the composite code word (Step S831: No and Step S832: No), decoding of the composite code word is performed (Step S833). The decoding of those is performed by the first decoding unit 212, the second decoding unit 214, and the third decoding unit 216 described with reference to FIG. 2. In the case where an error is not caused as a result of the decoding (Step S836: No), the decoding process is terminated. On the other hand, in the case where an error is caused as a result of the decoding, for example, in the case where an error correction of the page data in the page code word fails (Step S836: Yes), an error termination of the decoding process is performed. In this case, the memory controller 200 notifies the host computer 100 of the occurrence of the error.

[Procedure of Read Process (Process on Memory Side)]

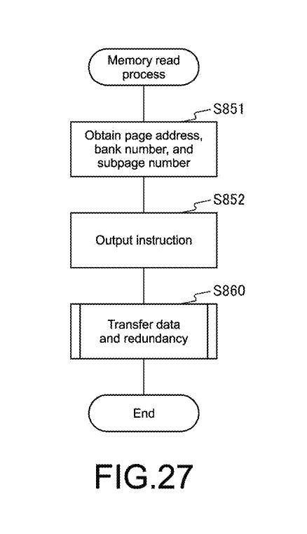

FIG. 27 is a flowchart showing an example of a procedure of a read process (memory) according to the first embodiment of the present technology. When the read request is issued from the memory controller 200, the memory 300 starts this process. First, the request is interpreted, a page address, a bank number, and a subpage number of the memory cell from which reading is performed are obtained (Step S851). Subsequently, an instruction for giving an instruction to perform a read is output to the banks of the memory cell array 308 corresponding to those (Step S852). At this time, in order to coincide timings of data transfer, it is necessary to make timings when the instruction is output different for each bank. Subsequently, the data and the redundancy output from the memory cell array 308 are transferred to the memory controller 200 (Step S860), and the read process is terminated.

[Procedure of Data and Redundancy Transfer Process (Process on Memory Side)]

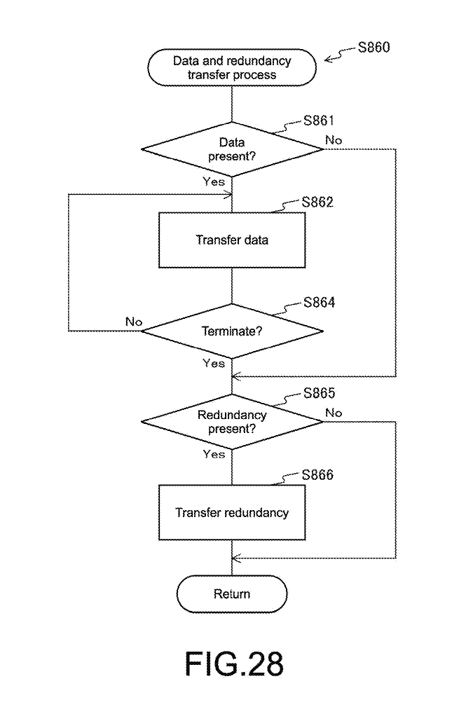

FIG. 28 is a flowchart showing an example of a procedure of a data and redundancy transfer process (memory) according to the first embodiment of the present technology. The memory 300 determines whether data that is to be transferred is present in the read target of the request or not (Step S861). In the case where read target is the page code word, the expansion code word, the composite code word, the page data, the expansion data, the code word block, or the data block (Step S861: Yes), data output from a specified bank is transferred to the memory controller 200 (Step S862). When the transfer of all data is terminated (Step S864: Yes), the process proceeds to the next. In the case where the transfer of all data is not terminated (Step S864: No), the process of Step S862 is performed again. On the other hand, in the case where the read target of the request is the page redundancy, the expansion redundancy, the composite redundancy, or the redundancy block (Step S861: No), the data is not transferred, and the process proceeds to the next. Subsequently, the memory 300 determines whether a redundancy that is to be transferred is present in the read target of the request or not (Step S865). In the case where the read target is the page code word, the expansion code word, the composite code word, the page redundancy, the expansion redundancy, the code word block, the composite redundancy, or the redundancy block (Step S865: Yes), the redundancy output from the redundancy bank is transferred to the memory controller 200 (Step S866). After that, the data and redundancy transfer process is terminated. On the other hand, in the case where the write target of the request the page data, the expansion data, or the data block (Step S865: No), the redundancy is not transferred, and the data and redundancy transfer process is terminated.

In the first embodiment of the present technology, the assumption is made in advance that the three kinds of redundancies, that is, the page redundancy, the expansion redundancy, and the composite redundancy are used, the data area and the redundancy area are disposed, and those are accessible by the same page address. As a result, it is possible to access the code word at a high speed. Further, at a time when the composite redundancy is used, a management table that indicates a relationship between the composite redundancy and the code word as a data part thereof can be omitted. Further, the kind of the redundancy with respect to the already stored data can be easily changed. For example, changing two pieces of page data stored as the page redundancy to the expansion redundancy only requires writing a new expansion redundancy into the redundancy area. Further, in the first embodiment of the present technology, the management information is stored in the redundancy area. At a time of accessing the management information, only accessing the redundancy area is required, so it is possible to eliminate unnecessary writing and reading for the data area. In the case where the composite redundancy is not used, it is also possible to store, in the subpage of the redundancy area secured as a storage area of the composite redundancy, another piece of data, for example, a write count in the bank.

As described above, according to the first embodiment, the data and the redundancies on the page basis are stored in the different areas of the memory, and those pieces of data, the redundancies, or the code words are accessed with the same page address, with the result that it is possible to improve convenience of the information processing system.

### 2. Second Embodiment

In the first embodiment described above, the redundancy is constituted of the parity and the management information. In contrast, in a second embodiment of the present technology, the redundancy has the parity, the management information, and the parity of the management information.

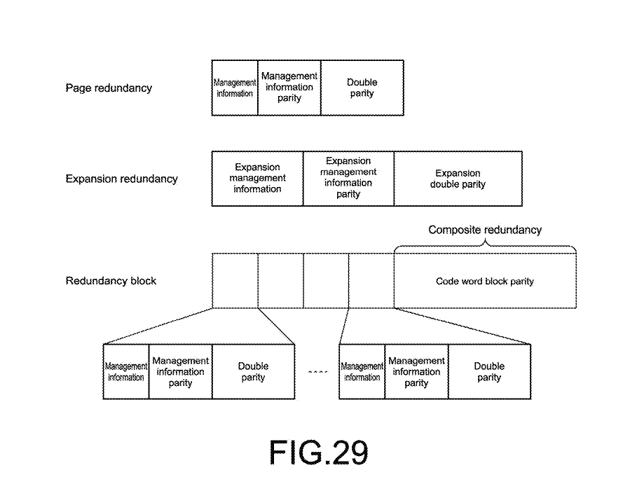

FIG. 29 is a diagram showing a configuration example of a redundancy according to the second embodiment of the present technology. A page redundancy shown in the figure is constituted of management information and a management information parity, which is a parity thereof, and a double parity. The double parity is a parity corresponding to the page data, the management information, and the management information parity. In a similar way, an expansion redundancy is constituted of an expansion management redundancy, an expansion management information parity, which is a parity thereof, and an expansion double parity. The expansion double parity is a parity corresponding to expansion data, the expansion management information, and the expansion management information parity. The same holds true for a page redundancy part in a code word block. The management information parity and the expansion management redundancy parity perform error detection and error correction for the management information, thereby protecting the management information.

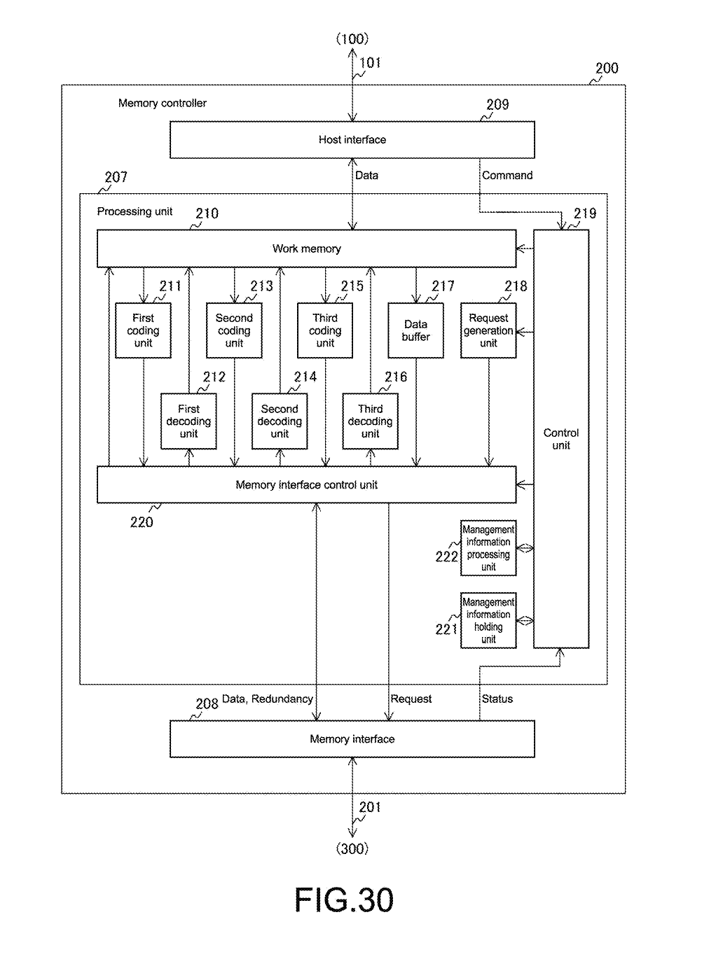

FIG. 30 is a diagram showing a configuration example of the memory controller according to the second embodiment of the present technology. The memory controller is different from the memory controller 200 according to the first embodiment of the present technology in that a management information processing unit 222 is provided thereto. The management information processing unit 222 performs generation of the management information parity and error correction of the management information by the management information parity. Further, the management information processing unit 222 also performs generation of the expansion management information parity and error correction of the expansion management information by the expansion management information parity. The control unit 219 controls the management information processing unit 222. Further, the first coding unit 211 shown in FIG. 30 generates the double parity from the page data, the management information, and the management information parity. The first decoding unit 212 reproduces the page data, the management information, and the management information parity by decoding the page code word. The second coding unit 213 generates the expansion double parity from the expansion data, the expansion management information, and the expansion management information parity. The second decoding unit 214 reproduces the expansion data, the expansion management information, and the expansion management information parity by decoding the expansion code word. The configuration of the memory controller 200 and the configuration of the memory 300 except the above are the same as the first embodiment of the present technology, so descriptions of the same parts will be omitted.

As described above, in the second embodiment, by using the redundancy constituted of the parity of the data, management information, and management information parity, the protection of the management information is reinforced, with the result that the reliability of the information processing system can be increased.

### Modified Example

In the second embodiment described above, the management information parity is stored in the subpage in the redundancy area along with the parity and management information. In contrast, in a modified example of the second embodiment of the present technology, a dedicated subpage of the management information parity is disposed in the redundancy area, and the management information parity is stored therein.

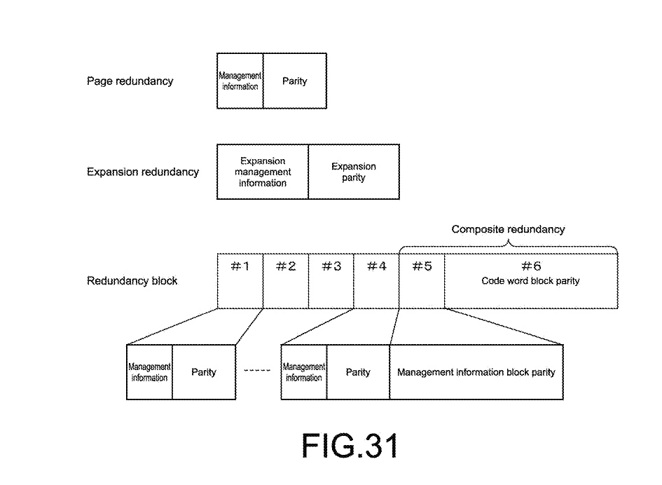

FIG. 31 is a diagram showing a configuration example of a redundancy in the modified example of the second embodiment of the present technology. The configurations of the page redundancy, the expansion redundancy, and the page redundancy part of the redundancy block can be the same as the configurations of the redundancy described with reference to FIG. 6. However, in the modified example of the second embodiment of the present technology, a parity (hereinafter, referred to as management information block parity) with respect to four pieces of management information included in the page redundancy part in the redundancy block is generated, and this is stored in one subpage. Therefore, the bank #5 of the memory cell array 308 in the modified example of the second embodiment of the present technology is provided with six subpages, and the subpage #5 is set as a subpage for storing the management information block parity.

The generation of the management information block parity is performed by the management information processing unit 222. That is, the management information processing unit 222 collectively generates the parities with respect to the four pieces of management information. The first coding unit 211 generates the parity from the page data and management information. The first decoding unit 212 decodes the page code word to reproduce the page data and the management information. The second coding unit 213 generates the expansion parity from the expansion data and the expansion management information. The second decoding unit 214 decodes the expansion code word, to reproduce the expansion data and the expansion management information. Further, in order to access the management information block parity, the request generation unit 218 has a function of generating a request to access the subpage #5 of the bank #5 of the memory cell array 308. The configuration except the above is the same as the memory 300 and the memory controller 200 described with reference to FIG. 30, so a description will be omitted. As in the second embodiment of the present technology, it is possible to reduce a process time as compared to the case where the management information parity is generated for each page redundancy.

As described above, also in the modified example of the second embodiment of the present technology, by using the management information parity, the protection of the management information is reinforced, and thus the reliability of the information processing system can be increased. Further, in the modified example of the second embodiment of the present technology, the parities are collectively generated with respect to the plurality of pieces of management information, and thus the process time can be reduced.

### 3. Third Embodiment

In the first embodiment, the memory controller 200 is provided with the data buffer 217. In contrast, in a third embodiment of the present technology, a method of transferring data and a redundancy is changed, thereby omitting the data buffer 217.

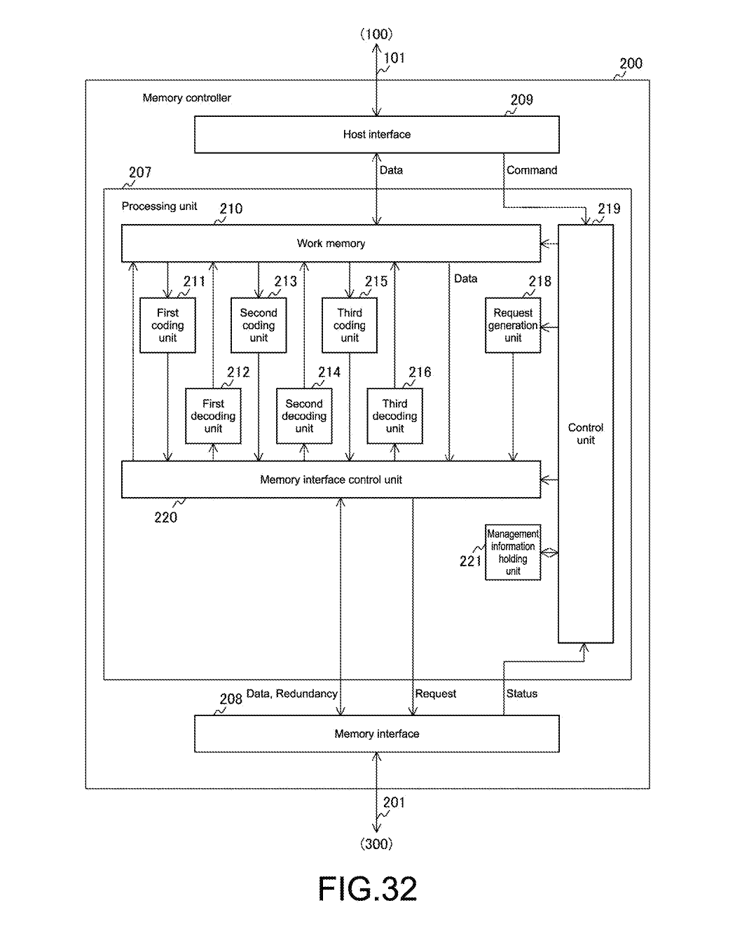

FIG. 32 is a diagram showing a configuration example of the memory controller according to the third embodiment of the present technology. The memory controller 200 according to the third embodiment of the present technology does not have to be provided with the data buffer 217. Further, even in the case where the data and the redundancy are output from the memory controller 200 with those temporally shifted, the memory control unit 311 of the memory 300 can perform a write in the memory cell array 308. The configurations of the memory controller 200 and the memory 300 except the above are the same as in the first embodiment of the present technology, so a description will be omitted.

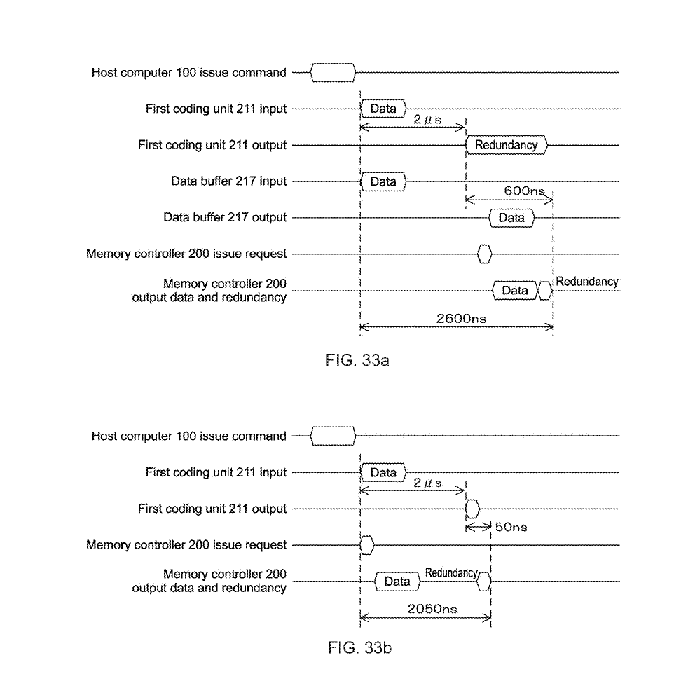

FIGS. 33a and 33b are a diagram showing a procedure of transfer of the data and the redundancy according to the third embodiment of the present technology. In the figure, a shows the procedure of transfer of the data and the redundancy according to the first embodiment of the present technology for comparison, and the case of writing the page code word is assumed. In the first embodiment of the present technology, the command is issued from the host computer 100, and when the page data is input to the work memory 210, the page data is transferred to the first coding unit 211 and the data buffer 217. Subsequently, the first coding unit 211 generates the redundancy. During this time, the page data is held in the data buffer 217. After the generation of the redundancy in first coding unit 211 is terminated, the request is issued, and the data buffer 217 is caused to output the page data. Finally, the generated redundancy is output. As described above, in the first embodiment of the present technology, the request, data, and redundancy are output to the memory 300 ceaselessly. It should be noted that, in FIG. 33a, a redundancy generation time is set to 2 μs, and a time from when the redundancy is generated until the output of the data and the redundancy is terminated is set to 600 ns, but those are merely examples and vary depending on the bit count or the like of the page data. In FIG. 33a, a time from when the input to the first coding unit 211 is started until the output of the data and the redundancy in the memory controller 200 is terminated is approximately 2600 ns.

In contrast, the memory controller 200 according to the third embodiment of the present technology outputs, during the coding, the request and data to the memory 300 prior thereto. After that, the generated page redundancy is output. This state is shown in FIG. 33b. In the third embodiment of the present technology, the page data and the page redundancy are not integrally output. However, the memory control unit 311 of the memory 300 interprets the request previously output, and stands by until the redundancy is output from the memory controller 200 in the case where the attribute is the “code word”. After that, for the redundancy output subsequently, the redundancy area is transferred to the bank. In this way, at a time of writing the page code word, even if there is a temporal difference between the outputs of the page data and the page redundancy, the memory 300 stores the data and the redundancy in the different areas, so it is possible to perform independent writing. As a result, a time from when the input to the first coding unit 211 is started until the output of the data and the redundancy in the memory controller 200 is terminated is reduced to approximately 2050 ns. In FIG. 33b, a time from when the redundancy is generated until the output is terminated is set to 50 ns. As in a of the figure, this is also merely an example of the output time. It should be noted that, even if the write target is the expansion code word and the composite code word, the memory controller 200 and the memory 300 perform the similar processes.

As described above, in the third embodiment of the present technology, those writings can be performed even in the case where the data and the redundancy are output at different timings from the memory controller 200 to the memory 300. As a result, the data buffer in the memory controller 200 can be omitted, which can make the configuration of the memory controller simple. Further, the transfer time of the data and the redundancy can be reduced.

### 4. Modified Example

In the above embodiment of the of the present technology, the redundancy is constituted of the parity and the management information. In contrast, in a modified example of the embodiment of the present technology, the redundancy is only constituted of the parity.

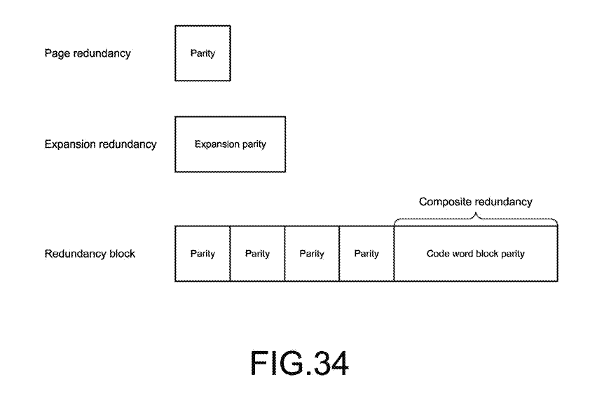

FIG. 34 is a diagram showing a configuration example of the redundancy in the modified example of the embodiment of the present technology. The page redundancy, the expansion redundancy, and the redundancy block are constituted of only parities. In the modified example of the embodiment of the present technology, the first coding unit 211 and the second coding unit 213 generate the redundancy or expansion redundancy which does not include the management information. Further, the first decoding unit 212 and the second decoding unit 214 reproduce the page data or expansion data from the code word. The remaining configuration of the memory controller 200 is the same as that in the memory controller 200 described with reference to FIG. 2, so a description will be omitted.

As described above, in the modified example of the embodiments of the present technology, because the redundancy does not include the management information, it is possible to eliminate a storage area of the memory cell array 308.

As described above, according to the embodiment of the present technology, the data and the redundancy on the page basis are stored in different areas in the memory, and the data, redundancy, or code word can be accessed by the same page address. As a result, it is possible to improve the convenience of the information processing system.

It should be noted that the above embodiments are merely examples for embodying the present technology, and the matters in the embodiments correspond to the matters to define the invention in claims. In a similar way, the matters to define the invention in claims correspond to the matters represented as the same names in the embodiments of the present technology. However, the present technology is not limited to the embodiments, and can be embodied by variously modifying the embodiments without departing from the gist of the present technology.

Further, the procedure described in the above embodiments may be grasped as a method having the series of procedures described above, and may be grasped as a program for causing a computer to execute the series of procedures or a recording medium for storing the program. As the storage medium, for example, a CD (Compact Disc), an MD (Mini Disc), a DVD (Digital Versatile Disc), a memory card, a Blu-ray (registered trademark) Disc), or the like can be used.

It should be noted that, the effects described in this specification are merely examples, and are not limited to those. Further, other effects may be exerted.

It should be noted that, the present technology can take the following configuration.

(1) A memory controller, including:

a request generation unit that generates, with respect to a nonvolatile memory including a data area in which data is stored and a redundancy area in which a redundancy for performing error detection and error correction of the data is stored, a request of requesting writing or reading for any one of the data, the redundancy, and a code word constituted of the data and the redundancy; and

a control unit that issues the generated request and controls writing and reading with respect to the nonvolatile memory.

(2) The memory controller according to (1), in which

the data is page data on a page basis,

the redundancy is a page redundancy for performing error detection and error correction of the page data,

the code word is a page code word constituted of the page data and the page redundancy, and

the request is a request of requesting writing or reading for any one of the page data, the page redundancy, and the page code word.

(3) The memory controller according to (2), in which

the data is expansion data including a plurality of pages and the page data,

the redundancy is expansion redundancy for performing error detection and error correction of the expansion data and the page redundancy,

the code word is an expansion code word constituted of the expansion data and the expansion redundancy and the page code word, and

the request is a request of requesting writing or reading for any one of the page data, the page redundancy, the page code word, the expansion data, the expansion redundancy, and the expansion code word.

(4) The memory controller according to (3), in which

the data is a code word block including a plurality of page code words, the expansion data, and the page data,

the redundancy is a composite redundancy for performing error detection and error correction of the code word block, the expansion redundancy, and the page redundancy,

the code word is a composite code word constituted of the code word block and the composite redundancy, the expansion code word, and the page code word, and

the request is a request of requesting writing or reading for any one of the page data, the page redundancy, the page code word, the expansion data, the expansion redundancy, the expansion code word, the code word block, the composite redundancy, and the composite code word.

(5) The memory controller according to (4), in which

the data is a data block constituted of a plurality of pieces of page data included in the code word block, the code word block, the expansion data, and the page data,

the redundancy is a redundancy block constituted of a plurality of page redundancies included in the code word block and the composite redundancy, the composite redundancy, the expansion redundancy, and the page redundancy,

the request is a request of requesting writing or reading for any one of the page data, the page redundancy, the page code word, the expansion data, the expansion redundancy, the expansion code word, the code word block, the composite redundancy, the composite code word, the data block, and the redundancy block.

(6) The memory controller according to (5), in which

the page redundancy is constituted of management information related to the page data and a parity for performing error detection and error correction of the page data and the management information,

the expansion redundancy is constituted of expansion management information related to the expansion data and an expansion parity for performing error detection and error correction of the expansion data and the expansion management information.

(7) The memory controller according to (6), in which

the composite redundancy is constituted of a management information block parity for performing error detection and error correction of a management information block including a plurality of pieces of management information included in the code word block and a code word block parity for performing error detection and error correction of the code word block.

(8) The memory controller according to (6), in which

the page redundancy is constituted of a management information parity for performing error detection and error correction of the management information, the management information, and a double parity for performing error detection and error correction of the page data, the management information, and the management information parity, and

the expansion redundancy is constituted of an expansion management information parity for performing error detection and error correction of the expansion management information, the expansion management information, and an expansion double parity for performing error detection and error correction of the expansion data, the expansion management information, and the expansion management information parity.

(9) The memory controller according to (5), further including:

a first coding unit that generates the page redundancy;

a first decoding unit that performs error detection and error correction of the page data included in the page code word by the page redundancy included in the page code word;

a second coding unit that generates the expansion redundancy;

a second decoding unit that performs error detection and error correction of the expansion data included in the expansion code word by the expansion redundancy included in the expansion code word;

a third coding unit that generates the composite redundancy; and

a third decoding unit that performs error detection and error correction of the code word block included in the composite code word by the composite redundancy included in the composite code word,

in which the control unit further controls a transfer of the page code word to the first decoding unit which is input from the nonvolatile memory in response to an output of the request of requesting the reading, a transfer of the expansion code word to the second decoding unit which is input from the nonvolatile memory in response to the output of the request of requesting reading, and a transfer of the composite code word to the third decoding unit which is input from the nonvolatile memory in response to the output of the request of requesting reading.

(10) A storage apparatus, including:

a nonvolatile memory including a data area in which data is stored and a redundancy area in which a redundancy for performing error detection and error correction of the data is stored; and

a memory controller that controls the nonvolatile memory,

in which the memory controller includes
a request generation unit that generates, with respect to the nonvolatile memory, a request of requesting writing or reading for any one of the data, the redundancy, and a code word constituted of the data and the redundancy, and
a control unit that issues the generated request and controls writing and reading with respect to the nonvolatile memory.

(11) The storage apparatus according to (10), in which

the nonvolatile memory is constituted of banks that store pages to which addresses are given with page addresses, the data area and the redundancy area are assigned to different banks, and the data and the redundancy that belong to the same code word are stored in the bank with the same page address.

(12) An information processing system, including:

a host computer that outputs a command of requesting writing or reading to a memory controller;

a nonvolatile memory including a data area in which data is stored and a redundancy area in which a redundancy for performing error detection and error correction of the data is stored; and

a memory controller that controls the nonvolatile memory on the basis of the command, in which

the memory controller includes
a request generation unit that generates, with respect to the nonvolatile memory, a request of requesting writing or reading for any one of the data, the redundancy, and a code word constituted of the data and the redundancy on the basis of the command, and
a control unit that issues the generated request and controls writing and reading with respect to the nonvolatile memory.

(13) A memory controller control method, including:

a request generation step of generating, with respect to a nonvolatile memory including a data area in which data is stored and a redundancy area in which a redundancy for performing error detection and error correction of the data is stored, a request of requesting writing or reading for any one of the data, the redundancy, and a code word constituted of the data and the redundancy; and

a control step of issuing the generated request and controlling writing and reading with respect to the nonvolatile memory.

### REFERENCE SIGNS LIST

100 host computer
101, 201 signal line
109, 209 host interface
110 processor
200 memory controller
207 processing unit
208, 309 memory interface
210 work memory
211 first coding unit
212 first decoding unit
213 second coding unit
214 second decoding unit
215 third coding unit
216 third decoding unit
217 data buffer
218 request generation unit
219 control unit
220, 310 memory interface control unit
221 management information holding unit
222 management information processing unit
300 memory
307 memory device control unit
308 memory cell array
311 memory control unit
312 ROM

1. A memory controller, comprising:
a request generation unit that generates, with respect to a nonvolatile memory including a data area in which data is stored and a redundancy area in which a redundancy for performing error detection and error correction of the data is stored, a request of requesting writing or reading for any one of the data, the redundancy, and a code word constituted of the data and the redundancy; and
a control unit that issues the generated request and controls writing and reading with respect to the nonvolatile memory.

2. The memory controller according to claim 1, wherein
the data is page data on a page basis,
the redundancy is a page redundancy for performing error detection and error correction of the page data,
the code word is a page code word constituted of the page data and the page redundancy, and
the request is a request of requesting writing or reading for any one of the page data, the page redundancy, and the page code word.

3. The memory controller according to claim 2, wherein
the data is expansion data including a plurality of pages and the page data,
the redundancy is expansion redundancy for performing error detection and error correction of the expansion data and the page redundancy,
the code word is an expansion code word constituted of the expansion data and the expansion redundancy and the page code word, and
the request is a request of requesting writing or reading for any one of the page data, the page redundancy, the page code word, the expansion data, the expansion redundancy, and the expansion code word.

4. The memory controller according to claim 3, wherein
the data is a code word block including a plurality of page code words, the expansion data, and the page data,
the redundancy is a composite redundancy for performing error detection and error correction of the code word block, the expansion redundancy, and the page redundancy,
the code word is a composite code word constituted of the code word block and the composite redundancy, the expansion code word, and the page code word, and
the request is a request of requesting writing or reading for any one of the page data, the page redundancy, the page code word, the expansion data, the expansion redundancy, the expansion code word, the code word block, the composite redundancy, and the composite code word.

5. The memory controller according to claim 4, wherein
the data is a data block constituted of a plurality of pieces of page data included in the code word block, the code word block, the expansion data, and the page data,
the redundancy is a redundancy block constituted of a plurality of page redundancies included in the code word block and the composite redundancy, the composite redundancy, the expansion redundancy, and the page redundancy, and
the request is a request of requesting writing or reading for any one of the page data, the page redundancy, the page code word, the expansion data, the expansion redundancy, the expansion code word, the code word block, the composite redundancy, the composite code word, the data block, and the redundancy block.

6. The memory controller according to claim 5, wherein
the page redundancy is constituted of management information related to the page data and a parity for performing error detection and error correction of the page data and the management information, and
the expansion redundancy is constituted of expansion management information related to the expansion data and an expansion parity for performing error detection and error correction of the expansion data and the expansion management information.

7. The memory controller according to claim 6, wherein
the composite redundancy is constituted of a management information block parity for performing error detection and error correction of a management information block including a plurality of pieces of management information included in the code word block and a code word block parity for performing error detection and error correction of the code word block.

8. The memory controller according to claim 6, wherein
the page redundancy is constituted of a management information parity for performing error detection and error correction of the management information, the management information, and a double parity for performing error detection and error correction of the page data, the management information, and the management information parity, and
the expansion redundancy is constituted of an expansion management information parity for performing error detection and error correction of the expansion management information, the expansion management information, and an expansion double parity for performing error detection and error correction of the expansion data, the expansion management information, and the expansion management information parity.

9. The memory controller according to claim 5, further comprising:
a first coding unit that generates the page redundancy;
a first decoding unit that performs error detection and error correction of the page data included in the page code word by the page redundancy included in the page code word;
a second coding unit that generates the expansion redundancy;
a second decoding unit that performs error detection and error correction of the expansion data included in the expansion code word by the expansion redundancy included in the expansion code word;
a third coding unit that generates the composite redundancy; and
a third decoding unit that performs error detection and error correction of the code word block included in the composite code word by the composite redundancy included in the composite code word,
wherein the control unit further controls a transfer of the page code word to the first decoding unit which is input from the nonvolatile memory in response to an output of the request of requesting the reading, a transfer of the expansion code word to the second decoding unit which is input from the nonvolatile memory in response to the output of the request of requesting reading, and a transfer of the composite code word to the third decoding unit which is input from the nonvolatile memory in response to the output of the request of requesting reading.

10. A storage apparatus, comprising:
a nonvolatile memory including a data area in which data is stored and a redundancy area in which a redundancy for performing error detection and error correction of the data is stored; and
a memory controller that controls the nonvolatile memory,
wherein the memory controller includes
a request generation unit that generates, with respect to the nonvolatile memory, a request of requesting writing or reading for any one of the data, the redundancy, and a code word constituted of the data and the redundancy, and
a control unit that issues the generated request and controls writing and reading with respect to the nonvolatile memory.

11. The storage apparatus according to claim 10, wherein
the nonvolatile memory is constituted of banks that store pages to which addresses are given with page addresses, the data area and the redundancy area are assigned to different banks, and the data and the redundancy that belong to the same code word are stored in the bank with the same page address.

12. An information processing system, comprising:
a host computer that outputs a command of requesting writing or reading to a memory controller;
a nonvolatile memory including a data area in which data is stored and a redundancy area in which a redundancy for performing error detection and error correction of the data is stored; and
a memory controller that controls the nonvolatile memory on the basis of the command, wherein
the memory controller includes
a request generation unit that generates, with respect to the nonvolatile memory, a request of requesting writing or reading for any one of the data, the redundancy, and a code word constituted of the data and the redundancy on the basis of the command, and
a control unit that issues the generated request and controls writing and reading with respect to the nonvolatile memory.

13. A memory controller control method, comprising:
a request generation step of generating, with respect to a nonvolatile memory including a data area in which data is stored and a redundancy area in which a redundancy for performing error detection and error correction of the data is stored, a request of requesting writing or reading for any one of the data, the redundancy, and a code word constituted of the data and the redundancy; and
a control step of issuing the generated request and controlling writing and reading with respect to the nonvolatile memory.
